(19) United States
(12) Patent Application Publication
(10) Pub. No.: US 2003/0209767 A1
(43) Pub. Date: Nov. 13, 2003

(54) Nonvolatile semiconductor memory device and method for fabricating the same

(75) Inventors: Koji Takahashi, Kawasaki (JP); Taketo Watanabe, Kawasaki (JP)

Correspondence Address: ARMSTRONG,WESTERMAN & HATTORI, LLP, 1725 K STREET, NW, SUITE 1000, WASHINGTON, DC, 20006, US

(73) Assignee: FUJITSU LIMITED, Kawasaki (JP)

(21) Appl. No.: 10/435,373

(22) Filed: May 12, 2003

(30) Foreign Application Priority Data
May 10, 2002 (JP) 2002-135688

(51) Int. Cl. H01L 21/336; H01L 29/76; H01L 31/062

(52) U.S. Cl. 257/390; 438/128; 438/290; 257/315; 438/201; 257/317

(57) ABSTRACT

The nonvolatile semiconductor memory device comprises a semiconductor substrate 10 with a trench 16 formed in the surface thereof, an impurity diffused region 24 formed in the surface of the semiconductor substrate 10 other than the region where the trench 16 is formed, an impurity diffused region 26 formed in the semiconductor substrate 10 at the bottom of the trench 16 and having a width smaller than that of the trench 16, a charge storage layer 28 of an insulating layer formed on the inside surface of the trench 16, and a conducting layer 36 formed on the charge storage layer 28 between the impurity diffused region 24 and the impurity diffused region 26. Whereby the punch-through between the impurity diffused region 24 and the impurity diffused region 26 can be effectively prevented, and resultantly writing can be efficiently performed.

### CROSS-REFERENCE TO RELATED APPLICATIONS

This application is based upon and claims the benefit of priority from the prior Japanese Patent Application No. 2002-135688, filed in May 10, 2002, the entire contents of which are incorporated herein by reference.

### BACKGROUND OF THE INVENTION

The present invention relates to a nonvolatile semiconductor memory device, more specifically a nonvolatile semiconductor memory device for storing charges in a charge storage layer of an insulating layer to thereby memorize information and a method for fabricating the same.

As rewritable nonvolatile semiconductor memory devices are known semiconductor memory devices, such as EEPROM, flash EEPROM, etc., which stores charges in the floating gate to store information. These semiconductor memory devices require the floating gate for storing information in addition to the control gate, which function as word lines. Accordingly, two conducting layers are required so as to form memory cell transistors.

As a nonvolatile semiconductor memory device which has a simple structure and can be easily higher-integrated is proposed a nonvolatile semiconductor memory device comprised of a single-gate memory cell transistor by using an insulating film as a charge storage layer.

The conventional nonvolatile semiconductor memory device having the single-gate structure will be explained with reference to FIGS. 62 to 65. FIG. 62 is a diagrammatic sectional view of the conventional nonvolatile semiconductor memory device. FIG. 63 is a view explaining the method of writing information in the conventional nonvolatile semiconductor memory device. FIGS. 64A and 64B are views explaining the method of reading information in the conventional nonvolatile semiconductor memory device. FIG. 65 is a view explaining the method of erasing information in the conventional nonvolatile semiconductor memory device.

Bit line diffused layers 102, 104 are formed in a silicon substrate 100. A charge storage layer 106 of an ONO (silicon oxide/silicon nitride/silicon oxide) film is formed on the silicon substrate 100 with the bit line diffused layers 102, 104 formed on. A word line 108 is formed on the charge storage layer 106.

In the conventional nonvolatile semiconductor memory device shown in FIG. 62, information writing is performed by injecting charges into the charge storage layer 106. When electrons are injected into the charge storage layer 28 by, e.g., channel hot electron injection or avalanche hot electron injection, the electrons are trapped in the silicon nitride film of the charge storage layer 106 or in the interface between the silicon nitride film and the silicon oxide film (FIG. 63). The state where charges are trapped in the charge storage layer 106 can be defined to be the state, for example, where information is written. In the writing by the hot electron injection, a voltage of +5V, for example, is applied to one bit line diffused layer 104, and a voltage of +10V, for example, is applied to the word line 108 while a voltage of another bit line diffused layer 102 and the silicon substrate 100 is, e.g., 0 V.

In information reading, written information is judged based on whether or not current flows between the bit line diffused layer 102 and the bit line diffused layer 104 when a prescribed voltage is applied to the word line 108 and the bit line diffused layers 102, 104. When no charge is trapped in the charge storage layer 106, as in the ordinary MOS transistors, a voltage is applied to the word lines 108, and one of the bit line diffused layer 102 and the bit line diffused layer 104, whereby a channel is formed on the front side of the silicon substrate 100 between the bit line diffused layer 102 and the bit line diffused layer 104, and current flows (data “1”) (FIG. 64A). When a charge is trapped in the charge storage layer 106, a channel is cut near the trap region of the charge, and no current flows between the bit line diffused layer 102 and the bit line diffused layer 104 (data “0”) (FIG. 64B). Thus, whether current flows between the bit line diffused layer 102 and the bit line diffused layer 104 is checked to thereby read written information.

Erasing of information is performed by injecting holes into the charge storage layer 106 by band-to-band tunneling. Specifically, a prescribed voltage is applied between the bit line diffused layers 102, 104 and the word line 108 to inject holes from the bit line diffused layers 102, 104 into the charge storage layer 106, whereby a negative charge of the electrons trapped in the charge storage layer 106 is compensated by a positive charge of the holes (FIG. 65). For example, a voltage of +7V and a voltage of −7V are applied respectively to the bit line diffused layer 104 and to the word line 108, whereby holes are injected from the bit line diffused layer 104 into the charge storage layer 106, and stored information can be erased.

However, in the conventional nonvolatile semiconductor memory device, in which information is written by injecting channel hot carriers, a pitch of the bit line diffused layer 102 and the bit line diffused layer 104 becomes smaller as the scaling advances, and punch-through makes it impossible to ensure a sufficient breakdown voltage. Accordingly, in the structure shown in FIG. 62, it is said that a pitch between the bit line diffused layer 102 and the bit line diffused layer 104 is limited to 0.1-0.07 μm, which makes it impossible to further micronize devices.

On the other hand, Laid-Open Japanese Patent Application No. 2001-77219 discloses a nonvolatile semiconductor memory device in which, as shown in FIG. 66, trenches 110 are provided in a silicon substrate 100, and one bit line diffused layer 102 is formed on the front surface of the silicon substrate between the trenches 110 while the other bit line diffused layer 104 is formed on the bottoms of the trenches 110. This nonvolatile semiconductor memory device, in which channels are formed on the sidewalls of the trenches 110, facilitates higher integration in comparison with the nonvolatile semiconductor memory device shown in FIG. 62, in which the channel is formed in plane. However, when the trenches 110 are made deep so as to ensure a channel length, the trenches 110 must have a high aspect ratio. The trenches 110 of a high aspect ratio make it difficult to bury the word line 108 in the trenches 110 and pattern the word line 108. Thus, this will makes the fabrication difficult.

### SUMMARY OF THE INVENTION

An object of the present invention is to provide a nonvolatile semiconductor memory device which stores information by storing charges in a charge storage layer of an insulating layer, which can ensure breakdown voltage between the bit line diffused layers (source-drain) even when an effective channel length is small, and a method for fabricating the same.

According to one aspect of the present invention, there is provided a nonvolatile semiconductor memory device comprising: a semiconductor substrate of a first conduction type with a trench formed in a surface thereof; a first impurity diffused region of a second conduction type formed in the surface other than a region where the trench is formed, of the semiconductor substrate; a second impurity diffused region of the second conduction type formed in the semiconductor substrate at a bottom of the trench and having a width smaller than that of the trench; a charge storage layer of an insulating layer formed on an inside surface of the trench; and a conducting layer formed on the charge storage layer between the first impurity diffused region and the second impurity diffused region.

According to another aspect of the present invention, there is provided a nonvolatile semiconductor memory device comprising: a semiconductor substrate of a first conduction type with a plurality of trenches formed in a surface thereof, the trenches extending in a first direction and being in parallel with each other; a plurality of first impurity diffused regions of a second conduction type formed in the surface other than regions where the trenches are formed, of the semiconductor substrate, the first impurity diffused regions extending in the first direction; a plurality of second impurity diffused regions of the second conduction type formed in the semiconductor substrate at bottoms of the trenches, the second impurity diffused regions extending in the first direction and having a width smaller than that of the trenches; a charge storage layer of an insulating layer formed on inside surfaces of the trenches; and a plurality of conducting layers formed on the charge storage layer, the conducting layers extending in a second direction intersecting the first direction and being in parallel with each other.

According to further another aspect of the present invention, there is provided a method for fabricating a nonvolatile semiconductor memory device comprising the steps of: forming a trench in a surface of a semiconductor substrate of a first conduction type; doping an impurity of a second conduction type in the semiconductor substrate with the trench formed in to form a first impurity diffused region of the second conduction type in the surface of the semiconductor substrate other than a region where the trench formed in and a second impurity diffused region of the second conduction type having a smaller width than the trench in the semiconductor substrate at a bottom of the trench, which are independent of each other; forming a charge storage layer of an insulating layer on an inside surface of the trench; and forming a conducting layer on the charge storage layer between the first impurity diffused region and the second impurity diffused region.

As described above, the nonvolatile semiconductor memory device according to the present invention, which stores charges in the charge storage layer of an insulating layer comprises the bit line diffused layers formed on the surface of the semiconductor substrate with the trench formed in and formed on the bottom of the trench, offset from the corner of the bottom of the trench, whereby the punch-through between the bit line diffused layers can be effectively prevented, and resultantly writing can be efficiently performed. The impurity diffused region of a conduction type opposite to that of the bit line diffused layers is formed, surrounding the bit line diffused layers, whereby the extension of the depletion layer between the bit line diffused layers can be further suppressed, and resultantly the punch-through immunity can be further improved.

### BRIEF DESCRIPTION OF THE DRAWINGS

FIG. 1 is a plan view of the nonvolatile semiconductor memory device according to a first embodiment of the present invention, which shows a structure thereof.

FIGS. 2A and 2B are diagrammatic sectional views of the nonvolatile semiconductor memory device according to the first embodiment of the present invention, which show the structure thereof.

FIG. 3 is a circuit diagram of the nonvolatile semiconductor memory device according to the first embodiment of the present invention, which show the structure thereof.

FIGS. 4A-4B and 5A-5B are views of electric field intensity distributions of the nonvolatile semiconductor memory device according to the first embodiment of the present invention at the time of writing, which were simulated by TCAD.

FIGS. 6A-6B and 7A-7B are views of distributions of carriers generated by impact ionization at the time of writing in the nonvolatile semiconductor memory device according to the first embodiment of the present invention, which were simulated by TCAD.

FIGS. 8, 10, 12, 14, 16, 19, and 22 are plan views of the nonvolatile semiconductor memory device according to the first embodiment of the present invention in the steps of the method for fabricating the same, which show the method.

FIGS. 9A-9B, 11A-11B, 13A-13B, 15A-15B, 17A-17C, 18A-18C, 20A-20C, 21A-21C, and 23A-23C are sectional views of the nonvolatile semiconductor memory device according to the first embodiment of the present invention in the steps of the method for fabricating the same, which show the method.

FIGS. 24A and 24B are diagrammatic sectional views of the nonvolatile semiconductor memory device according to a second embodiment of the present invention, which show the structure thereof.

FIGS. 25A-25B, 26A-26B, and 27A-27C are sectional views of the nonvolatile semiconductor memory device according to the second embodiment of the present invention in the steps of the method for fabricating the same, which show the method.

FIGS. 28A and 28B are diagrammatic sectional views of the nonvolatile semiconductor memory device according to a third embodiment of the present invention, which show the structure thereof.

FIGS. 29A-29D, 30A-30B, 31A-31B, and 32A-32B are sectional views of the nonvolatile semiconductor memory device according to the third embodiment of the present invention in the steps of the method for fabricating the same, which show the method.

FIGS. 33A and 33B are diagrammatic sectional views of the nonvolatile semiconductor memory device according to a fourth embodiment of the present invention, which show the structure thereof.

FIGS. 34A-34B, 35A-35B, 36A-36B, 37A-37B, and 38A-38B are sectional views of the nonvolatile semiconductor memory device according to the fourth embodiment of the present invention in the steps of the method for fabricating the same, which show the method.

FIGS. 39A and 39B are diagrammatic sectional views of the nonvolatile semiconductor memory device according to a fifth embodiment of the present invention, which show the structure thereof.

FIGS. 40, 42, 44, 46, 48, 50, 53, and 56 are plan views of the nonvolatile semiconductor memory device according to the fifth embodiment of the present invention in the steps of the method for fabricating the same, which show the method.

FIGS. 41, 43A-43B, 45A-45B, 47A-47B, 49A-49B, 51A-51C, 52A-52C, 54A-54C, 55A-55C, and 57A-57C are sectional views of the nonvolatile semiconductor memory device according to the fifth embodiment of the present invention in the steps of the method for fabricating the same, which show the method.

FIGS. 58A and 58B are diagrammatic sectional views of the nonvolatile semiconductor memory device according to a sixth embodiment of the present invention, which show the structure thereof.

FIGS. 59A-59C and 60A-60C are diagrammatic sectional views of the nonvolatile semiconductor memory device according to the sixth embodiment of the present invention in the steps of the method for fabricating the same, which show the method.

FIG. 61 is a diagrammatic sectional view of the nonvolatile semiconductor memory device according to a modification of the embodiments of the present invention, which shows the structure thereof.

FIG. 62 is a diagrammatic sectional view of the conventional nonvolatile semiconductor memory device, which show the structure thereof.

FIG. 63 is a view explaining the method of writing information in the conventional nonvolatile semiconductor memory device.

FIGS. 64A and 64B are views explaining the method of reading information in the conventional nonvolatile semiconductor memory device shown in FIG. 62.

FIG. 65 is a view explaining the method of erasing information in the conventional nonvolatile semiconductor memory device shown in FIG. 62.

FIG. 66 is a diagrammatic sectional view of another conventional nonvolatile semiconductor memory device, which shows the structure thereof.

### DETAILED DESCRIPTION OF THE INVENTION

[A First Embodiment]

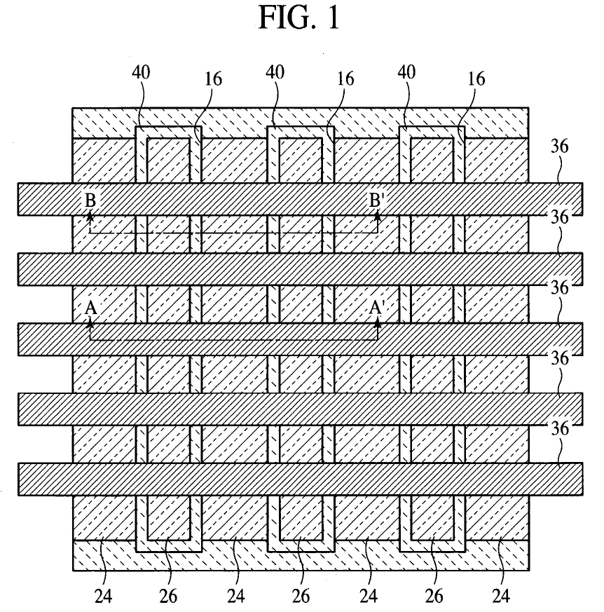

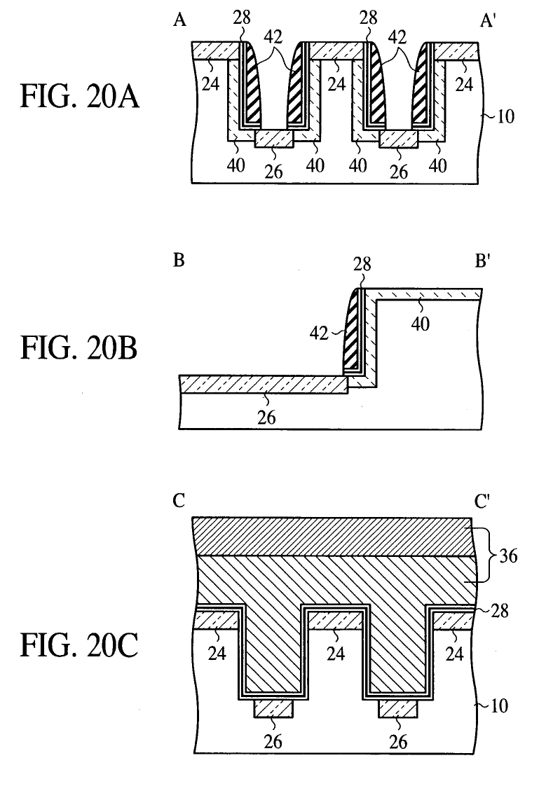

The nonvolatile semiconductor memory device according to a first embodiment of the present invention and the method for fabricating the nonvolatile semiconductor memory device will be explained with reference to FIGS. 1 to 23C.

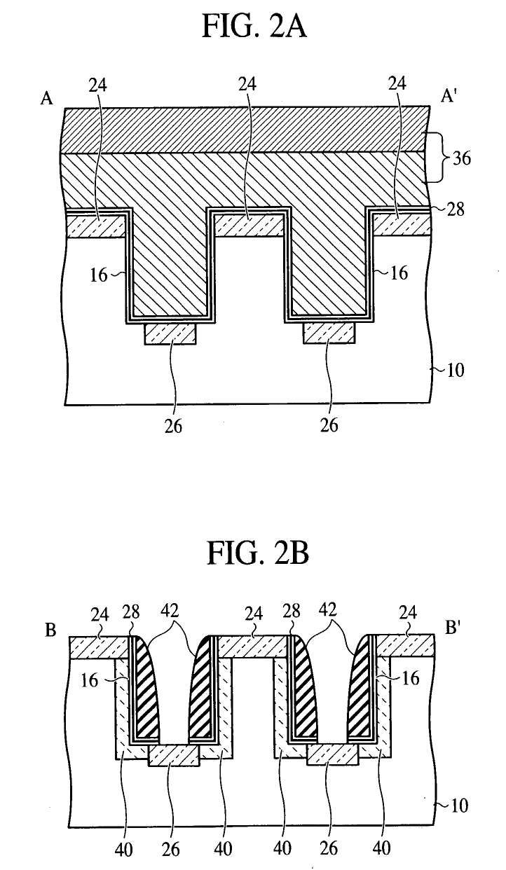

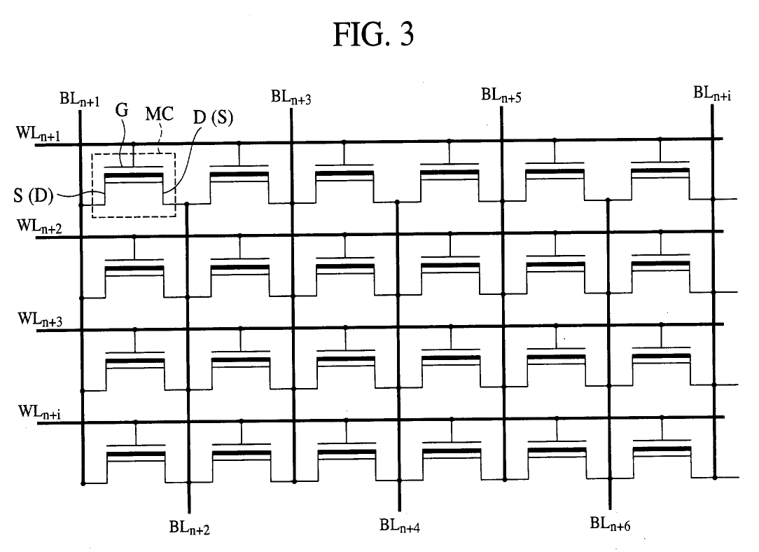

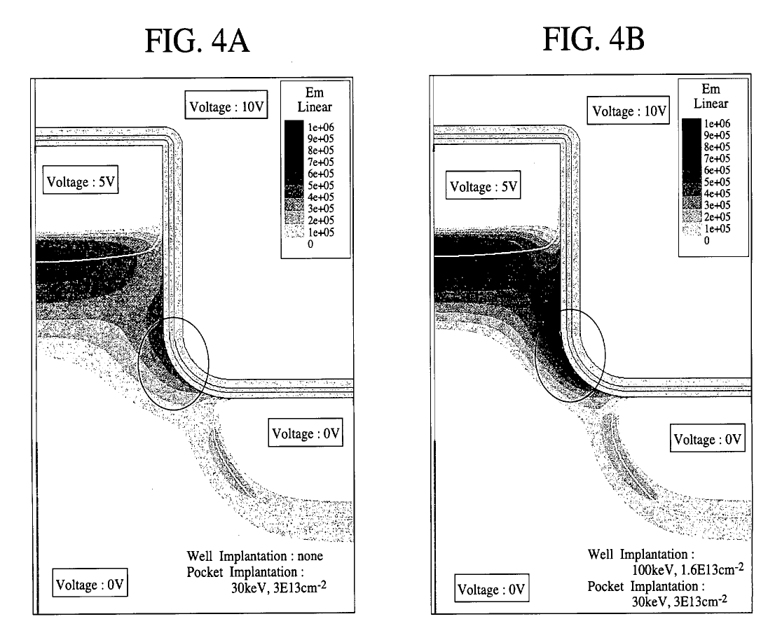

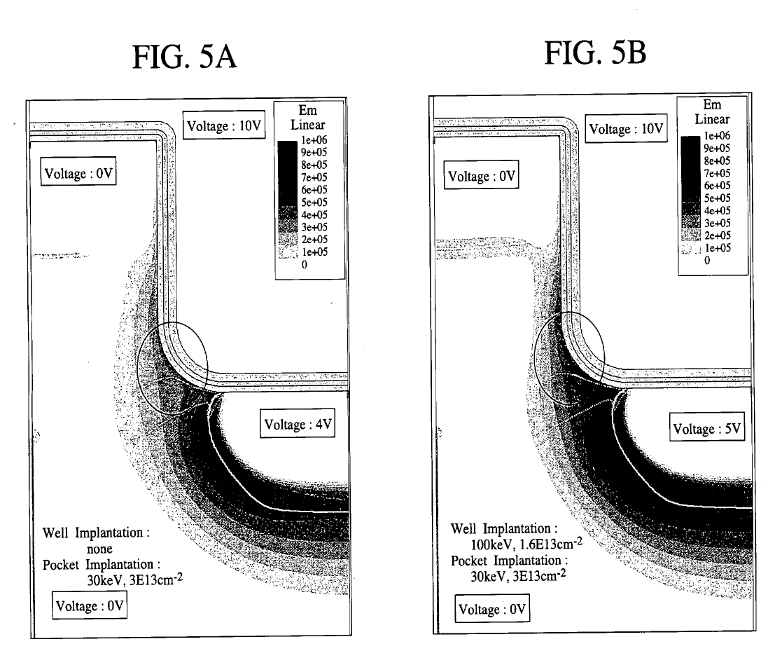

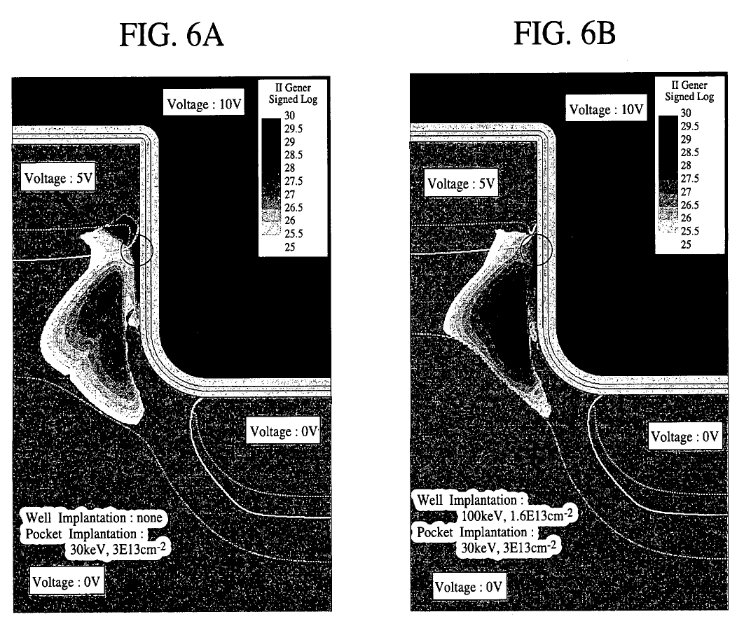

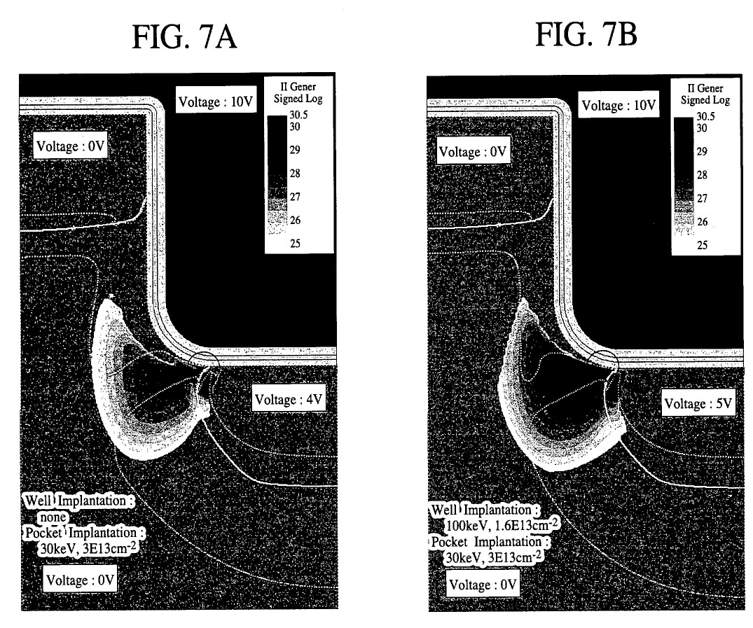

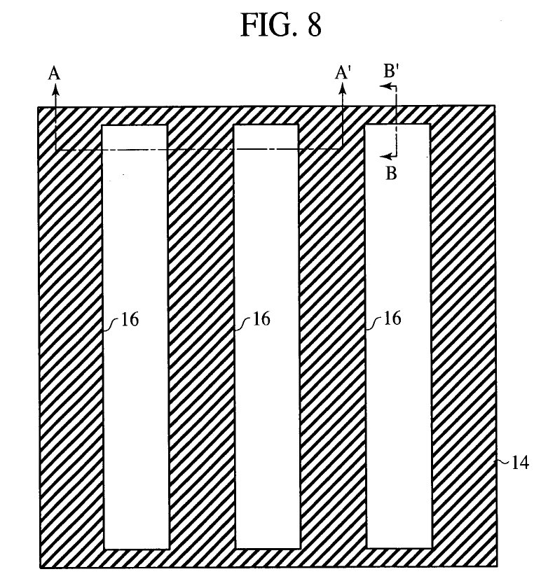

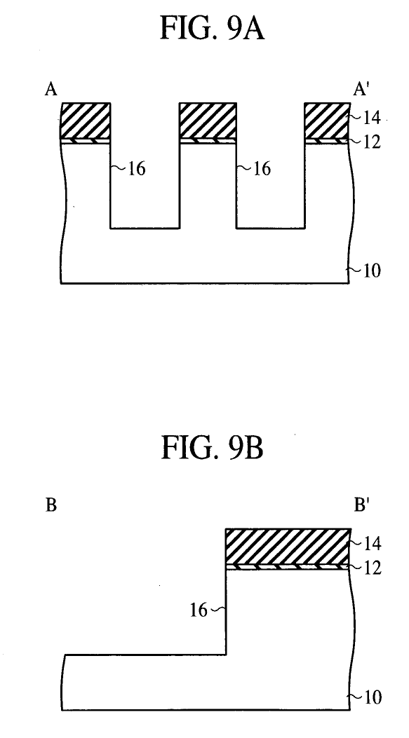

FIG. 1 is a plan view of the nonvolatile semiconductor memory device according to the present embodiment, which shows a structure thereof. FIGS. 2A and 2B are diagrammatic sectional views of the nonvolatile semiconductor memory device according to the present embodiment, which show the structure thereof. FIG. 3 is a circuit diagram of the nonvolatile semiconductor memory device according to the present embodiment, which shows the structure thereof. FIGS. 4A, 4B, 5A, and 5B are views of electric field intensity distributions of the nonvolatile semiconductor memory device according to the present embodiment at the time of writing, which were simulated by TCAD. FIGS. 6A, 6B, 7A, and 7B are views of distributions of carriers generated by impact ionization at the time of writing in the nonvolatile semiconductor memory device according to the present embodiment, which were simulated by TCAD. FIGS. 8, 10, 12, 14, 16, 19, and 22 are plan views of the nonvolatile semiconductor memory device according to the present embodiment in the steps of the method for fabricating the same, which show the method. FIGS. 9A-9B, 11A-11B, 13A-13B, 15A-15B, 17A-17C, 18A-18C, 20A-20C, 21A-21C, and 23A-23C are sectional views of the nonvolatile semiconductor memory device according to the present embodiment in the steps of the method for fabricating the same, which show the method.

First, the structure of the nonvolatile semiconductor memory device according to the present embodiment will be explained with reference to FIGS. 1 to 3. FIG. 2A is the diagrammatic sectional view along the line A-A′ in FIG. 1. FIG. 2B is the diagrammatic sectional view along the line B-B′ in FIG. 1.

Trenches 16 are formed in a silicon substrate 10. As shown in FIG. 1, the trenches 16 are formed in stripes extended in one direction. Bit line diffused layers 24 are formed on the surface of the silicon substrate 10 in the regions between the trenches 16 adjacent to each other. On the bottoms of the trenches 16, Bit line diffused layers 16 are formed, offset from the corners of the bottoms of the trenches 16 by a prescribed distance. That is, the bit line diffused layers 16 have a width which is smaller than that of the trenches 16 by an offset amount.

A charge storage layer 28 of an ONO (silicon oxide/silicon nitride/silicon oxide) film is formed on the surface of the silicon substrate 10 with the trenches 16 formed in. Word lines 36 are formed on the charge storage layer 18 extending in a direction intersecting the direction of extension of the trenches 16.

As shown in FIG. 2B, between the bit line diffused layers 24 and the bit line diffused layers 26 in the regions between the word lines 36, channel cut diffused layers 40 for preventing the formation of channels in these regions are formed. Sidewall insulating films 42 are formed on the sidewalls of the trenches 16 in the regions between the word lines 36.

A plurality of memory transistors each comprising one of the bit line diffused layers 24, 26 as the source diffused layer, the other of the bit line diffused layers 24, 26 as the drain diffused layer, and the word line 36 as the gate electrode are formed on the silicon substrate 10.

The circuit diagram of the nonvolatile semiconductor memory device shown in FIGS. 1, 2A and 2B is as shown in FIG. 3. That is, an NOR-type memory cell array comprising a plurality of bit lines BL and a plurality of word lines WL intersecting each other, the gate electrodes G connected to the word lines WL, and the source electrodes S and the drain electrodes D connected to the bit lines BL is formed.

Next, the operation of the nonvolatile semiconductor memory device according to the present embodiment will be explained with reference to FIGS. 1 to 7B.

Information writing is performed by injecting a charge into the charge storage layer 28. When electrons are injected into the charge storage layer 28 by, e.g., channel hot electron injection or avalanche hot electron injection, the electrons are trapped in the silicon nitride film or in the interface between the silicon nitride film and the silicon oxide film. The state where a charge is trapped in the charge storage layer 28 can be defined as the state where, for example, information is written. In writing by hot electron injection, a voltage of, e.g., +5 V is applied to one of the bit line diffused layer, a voltage of, e.g., +10 V is applied to the word line, and a voltage of 0 V is applied to the other bit line diffused layer and the substrate (wells).

FIGS. 4A, 4B, 5A, and 5B show electric field intensity distributions of the nonvolatile semiconductor memory device according to the present embodiment in writing, which were simulated by TCAD. FIGS. 4A and 4B are the electric field intensity distributions at the time when the voltage is applied to the bit line diffused layer on the surface of the substrate. FIGS. 5A and 5B are the electric field intensity distributions at the time when the voltage is applied to the bit line diffused layer on the bottom of the trench. In FIGS. 4A and 5A, no wells are formed in the memory cell region. In FIGS. 4B and 5B, wells are formed in the memory cell region.

As shown, the bit line diffused layers are provided on the surface of the substrate and the bottom of the trench, and the bit line diffused layer on the bottom of the trench is offset from the corner of the bottom of the trench, whereby electric field from the word line can be strongly influential to electric field distributions between the bit line diffused layers (the circled regions in the drawings). That is, the electric field intensity is higher at the corner of the bottom of the trench, and the extension of the depletion layer from the drain (the bit line diffused layer on the surface of the substrate) can be suppressed. Resultantly, the punch-through between the bit line diffused layers can be suppressed. In suppressing the punch-through between the bit line diffused layers it is very effective to offset the bit line diffused layer on the bottom of the trench from the corner.

In comparing the case with the well formed with the case without the well formed, the former has electric field which is the stronger for the well formed, but the electric field distributions of both cases have the same tendency.

FIGS. 6A, 6B, 7A and 7B show distributions of carriers generated by impact ionization in the nonvolatile semiconductor memory device according to the present embodiment in writing, which were simulated by TCAD. FIGS. 6A and 6B are the carrier distributions at the time when the voltage is applied to the bit line diffused layer on the surface of the substrate. FIGS. 7A and 7B are the carrier distributions at the time when the voltage is applied to the bit line diffused layer on the bottom of the trench. In FIGS. 6A and 7A, no well is formed in the memory cell region. In FIGS. 6B and 7B, the well is formed in the memory cell region.

When the voltage is applied to the bit line diffused layer on the surface of the substrate, as shown in FIGS. 6A and 6B, the impact ionization takes place more at the end of the channel region near the bit line diffused layer on the surface of the substrate (circled regions in the drawings) That is, in these regions the writing efficiency is highest. In comparison of the case with the well formed with the case without the well formed, the former has a small region where the impact ionization takes place at higher rates. The case with the well formed will be able to make the carrier distribution narrower.

On the other hand, when the voltage is applied to the bit line diffused layer on the bottom of the trench, as shown in FIGS. 7A and 7B, the impact ionization takes place more at the end of the channel region near the bit line diffused layer on the bottom of the trench. Thus, the writing efficiency is highest in these regions. In comparison of the case with the well formed with the case without the well formed, the former has a small region where the impact ionization takes place at higher rates. The case with the well formed will be able to make the carrier distribution narrower.

As described above, the nonvolatile semiconductor memory device according to the present embodiment can effectively prevent the punch-through between the bit line diffused layers, and the writing can be efficiently performed. The voltage is applied to the bit line diffused layer on the surface of the substrate, and the voltage is applied to the bit line diffused layer on the bottom of the trench, whereby charges can be injected in different regions of the charge storage layer, and two bits of information can be stored in one memory cell formed of one transistor.

In reading information, written information is judged based on whether or not current flows between the bit line diffused layers 24, 26 when a prescribed voltage is applied to the bit line diffused layers 24, 26.

When no charge is trapped in the charge storage layer 28, as in the ordinary MOS transistors, the voltage is applied to the word line 36 and one of the bit line diffused layers 24, 26 to thereby form the channel on the surface of the silicon substrate 10 between the bit line diffused layers 24, 26, and current flows (data “1”). However, when the charge is trapped in the charge storage layer 28, the channel is cut near the region where the charge is trapped, and no current flows between the bit line diffused layers 24, 26 (data “0”). Accordingly, whether or not current flows between the bit line diffused layers 24, 26 is checked to thereby read written information.

Erasing of information is performed by injecting holes into the charge storage layer 28 by band-to-band tunneling. Specifically, a prescribed voltage is applied between the bit line diffused layer on the side where charges are stored, and the word line to inject holes from the bit line diffused layer into the charge storage layer, whereby a negative charge of electrons trapped in the charge storage layer is compensated by a positive charge of holes. For example, a voltage of +7 V and a voltage of −7 V are applied respectively to the bit line diffused layer and the word line, holes are injected from the bit line diffused layer into the charge storage layer, and stored information is erased.

It is possible that voltages are concurrently applied to the bit line diffused layers 24, 26, whereby information stored in the charge storage layer on the side of the bit line diffused layer 24 and information stored in the charge storage layer on the side of the bit line diffused layer 26 are erased at once. The erasing may be performed by avalanche hot holes injection or Fowler-Nordheim (FN) tunneling.

Next, the method for fabricating the nonvolatile semiconductor memory device according to the present embodiment will be explained with reference to FIGS. 8 to 23C.

First, a silicon oxide film 12 of, e.g., a 10-20 nm-thick is formed on a p-type silicon substrate 10 by thermal oxidation at, e.g., 900-950° C.

Next, a silicon nitride film 14 of, e.g., a 100-150 nm-thick is deposited on the silicon oxide film 12 by, e.g., CVD.

Then, the silicon nitride film 14, the silicon oxide film 12 and the silicon substrate 10 are etched by using photolithography and anisotropical etching to pattern the silicon nitride film 14 and the silicon oxide film 12 while forming the trenches 16 of, e.g., 50-300 nm-depth in the silicon substrate 10 (FIGS. 9A and 9B). The trenches 16 are formed in stripes which are extended in the longitudinal direction of the drawing.

At this time, it is preferable that the etching of the silicon substrate 10 uses, e.g., a mixed gas of HBr/Cl₂/CF₄/O₂, flow rates of HBr and Cl₂ are lowered before the etching is completed while a flow rate of O₂ is raised. This rounds the corners of the bottoms of the trenches 16 so that the concentration of electric fields on the corners can be mitigated.

The trenches 16 maybe formed concurrently with formation of trenches (not shown) for isolating devices of peripheral circuits. In a case that the trenches for the peripheral circuits and the trenches 16 have different depths, an aspect difference, for example, can be utilized. It is also possible to form the trenches 16 and the trenches for the peripheral circuits separately by repeating lithography and anisotropical etching. However, in a case that the trenches 16 are formed before the trenches for the peripheral circuits, the insulating film for filling the trenches for the peripheral circuits is deposited also in the trenches 16, and the insulating film must be removed.

It is also possible to form a p-well in the silicon substrate 10, and the trenches 16, etc. may be formed in the p-well. The p-well is formed, whereby a profile of the junction with the n⁺ diffused layer at the trench bottoms can be made proper. The p-well can be formed by implanting boron ions for example, at 70-150 keV acceleration energy and to a dose of a 1×10¹³-3×10¹³ cm⁻².

Next, a silicon oxide film 18 of, e.g., a 5-20 nm-thick is formed in the trenches 16 by thermal oxidation at, e.g., 800-900° C.

Then, the silicon nitride film 14 is removed by, e.g., wet etching using boiled phosphoric acid.

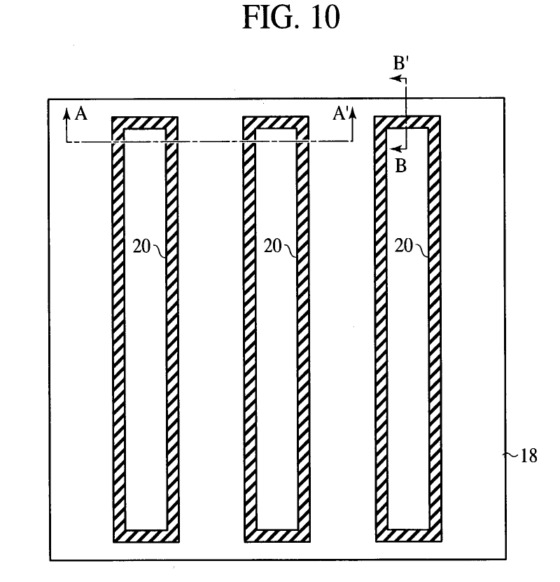

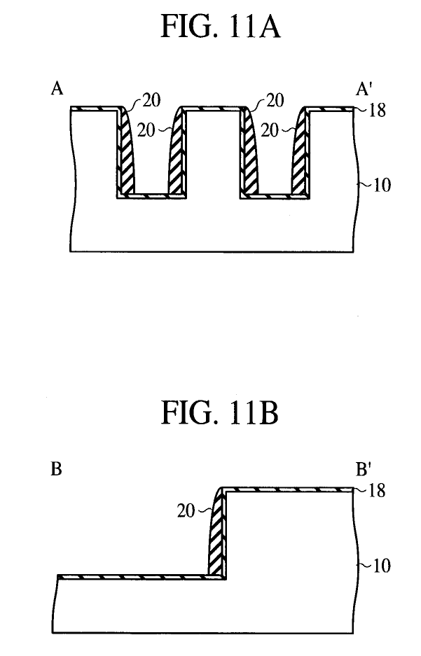

Next, a silicon nitride film of, e.g., a 50-150 nm-thick is deposited on the entire surface by, e.g., CVD and is anisotropically etched back to form the sidewall insulating film 20 of the silicon nitride film on the sidewalls of the trenches 16 (FIGS. 10, 11A, and 11B).

The silicon oxide film 18 may be formed after the silicon nitride film 14 and the silicon oxide film 12 have been removed, whereby a thickness of the silicon oxide film on the bottoms of the trenches 16 can be equal to a thickness of the silicon oxide film on the surface of the silicon substrate 10.

Next, a photoresist film 22 exposing the memory cell region is formed by photolithography.

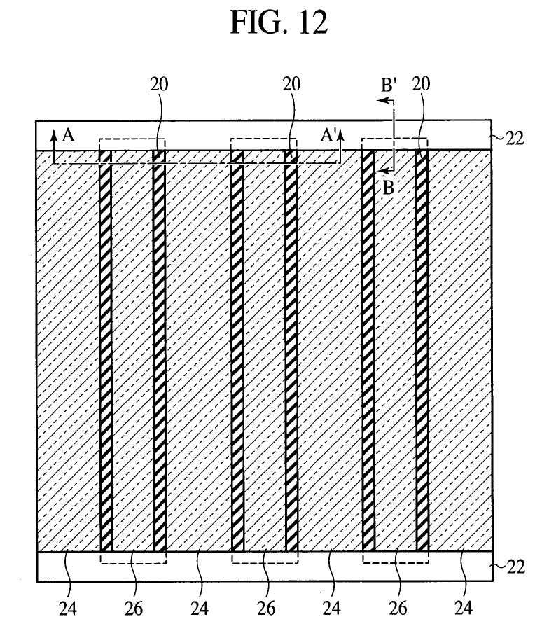

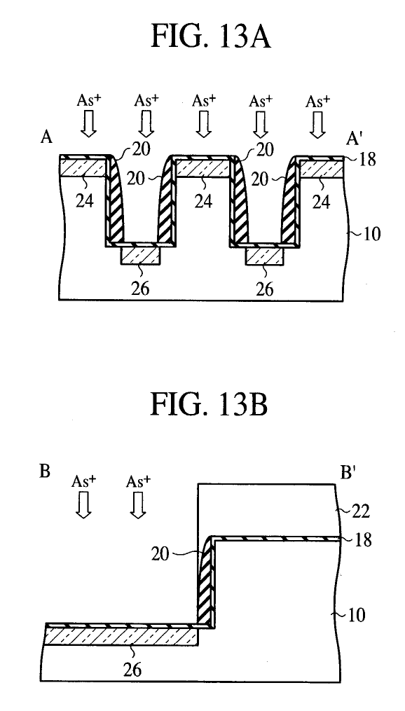

Then, with the photoresist film 22 as a mask, for example, arsenic ions (As⁺) are implanted at 30-80 keV acceleration energy, at a 0° tilt angle to the normal direction of the substrate, and to a dose of 1×10¹⁵-3×10¹⁵ cm⁻² to form the bit line diffused layers 24 on the surface of the silicon substrate 10 in the region between the adjacent trenches 16, and the bit line diffused layers 26 on the bottoms of the trenches 16, offset from the corners by a thickness of the sidewall insulating film 20 (FIGS. 12, 13A, and 13B).

Then, the sidewall insulating film 20 of the silicon nitride film is removed by, e.g., wet etching using boiled phosphoric acid.

Next, the silicon oxide film 18 is removed by, e.g., wet etching using an aqueous solution of hydrofluoric acid.

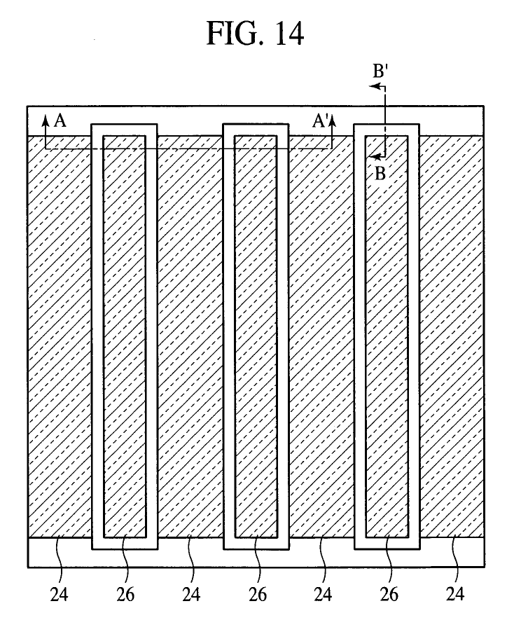

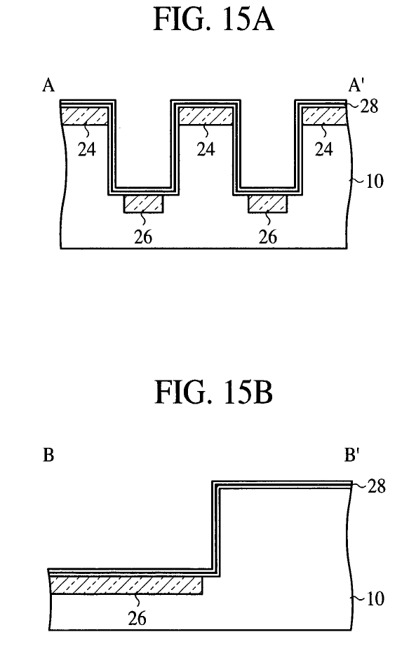

Then, a 3-10 nm-thick silicon oxide film, a 8-16 nm-thick silicon nitride film and a 4-10 nm-thick silicon oxide film are sequentially formed respectively by, e.g., thermal oxidation at 800-1100° C. or CVD at 700-800° C., by CVD at 600-800° C. CVD, and by wet oxidation at 900-1100° C. Thus, the charge storage layer 28 of the ONO (SiO—SiN—SiO) film structure is formed (FIG. 14, and FIGS. 15A and 15B).

The silicon nitride film may be 5-10 nm-thick, and the uppermost silicon oxide film may be formed by CVD.

Then, a photoresist film (not shown) covering the memory cell region is formed by photolithography, and then with the photoresist film as a mask, the charge storage layer 28 is etched. Thus, the charge storage layer 28 in the peripheral circuit region is removed.

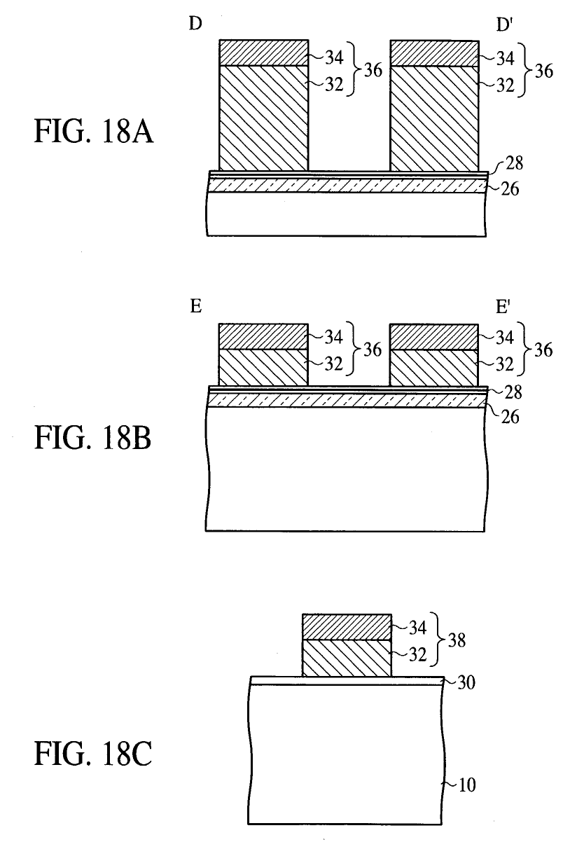

Next, a 5-15 nm-thick silicon oxide film is formed by thermal oxidation at, e.g., 800-1100° C. Thus, a gate insulating film 30 for the peripheral circuit transistors is formed (see FIG. 18C).

Then, an amorphous silicon film 32 of, e.g., a 100-200 nm-thick, which is doped with, e.g., a 2×10²⁰-3×10²¹ cm⁻³ of arsenic, and a tungsten silicide film 34 of, e.g., a 100-180 nm-thick are deposited on the entire surface by, e.g., CVD.

Then, boron ions (B⁺), for example, are implanted from two directions of 135° and 315° twist angles or 45° and 225° twist angles to the extending direction of the bit line diffused layers 24, 26, at 20-40 keV acceleration energy, at a 15-30° tilt angle and to a dose of 5×10¹²-1×10¹³ cm⁻² dose for one direction.

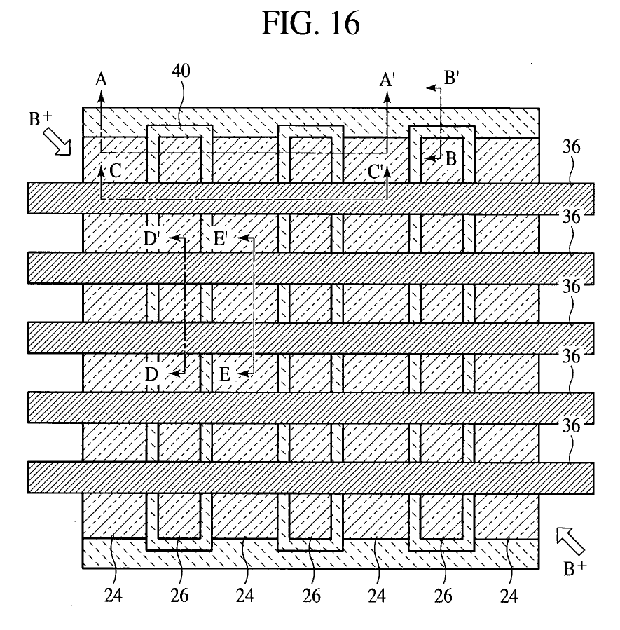

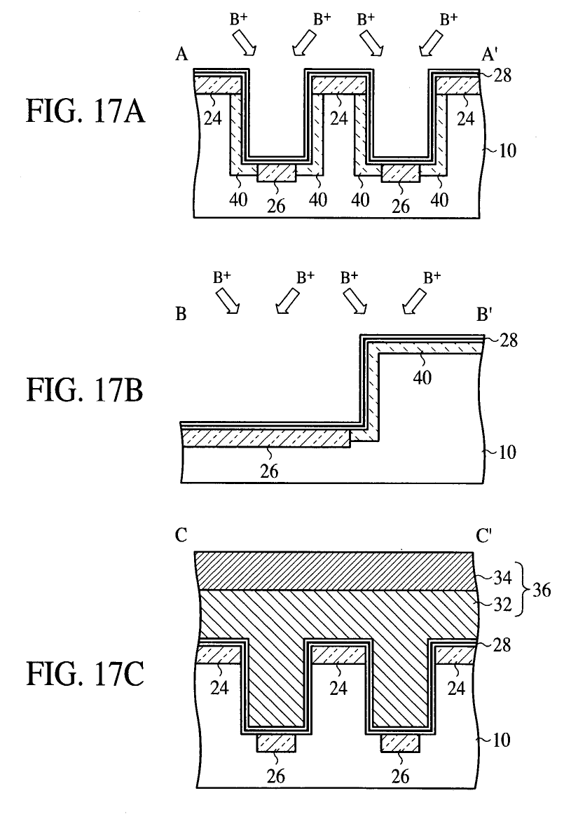

The boron ions implanted in these two directions are introduced into both sidewalls of the trenches 16 and form the channel cut diffused layer 40 between the bit line diffused layers 24 and the bit line diffused layers 26 in the regions between the word lines 36, for the prevention of the formation of channels in these regions (FIGS. 16, 17A, and 17B).

Then, a photoresist film covering the memory cell region is formed as required, and then with the gate electrode 38 as a mask arsenic ions, for example, are implanted to form in the silicon substrate 10 on both sides of the gate electrode 38 the impurity diffused regions 44 which are to be lightly-doped regions of the LDD structure or extension regions of the extension S/D structure.

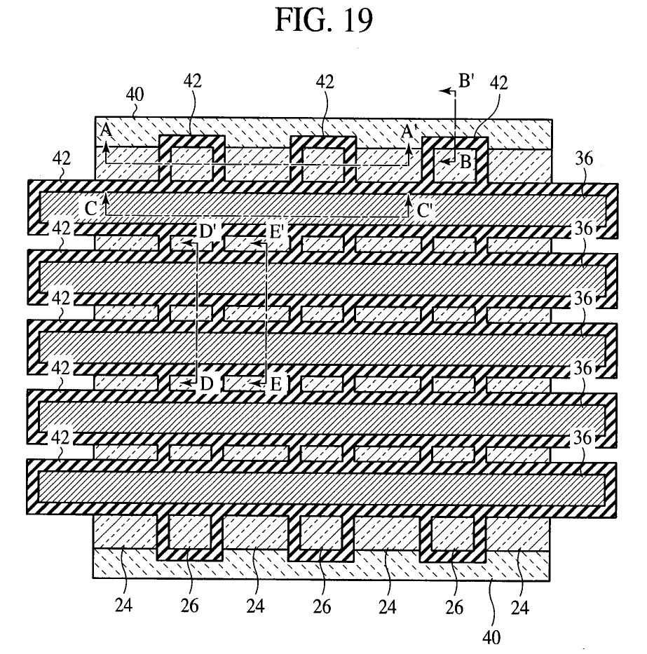

Next, a silicon nitride film of, e.g., a 50-150 nm-thick is deposited on the entire surface by, e.g., CVD and is anisotropically etched back to form the sidewall insulating film 42 of the silicon nitride film on the sidewalls of the trenches 16, the word lines 36 and the gate electrodes 38 (FIGS. 19, 20A, 20B, 21A, and 21B).

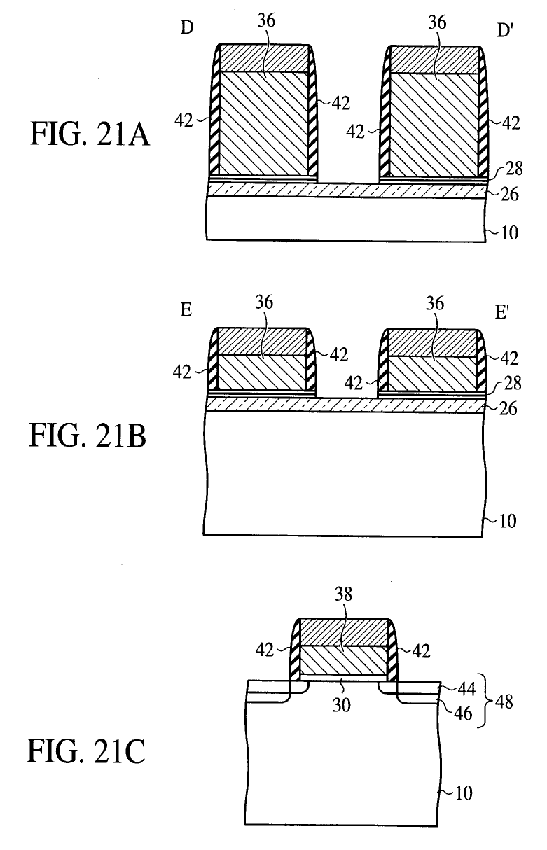

Then, a photoresist film covering the memory cell region is formed. Then, with the gate electrode 38 and the sidewall insulating film 42 as a mask, arsenic ions, for example are implanted to form in the silicon substrate 10 on both sides of the gate electrode 38 the impurity diffused regions 46. Thus, the source/drain diffused layer 48 of the impurity diffused regions 44, 46 are formed (FIG. 21C).

Next, a silicon oxide film of, e.g., a 500-1000 nm-thick is formed on the entire surface by, e.g., CVD. The surface of the silicon oxide film is polished by, e.g., CMP to form an inter-layer insulating film 50 of the silicon oxide film.

Then, contact holes 52, contact holes 54 and contact holes 56 are formed in the inter-layer insulating film 50 by lithography and anisotropical etching respectively down to the bit line diffused layer 24s, down to the bit lien diffused layers 26 and down to the source/drain diffused layers 48. At this time, the contact holes 54, 56 may be opened by self-alignment with the sidewall insulating film 42.

Next, a 10 nm-thick titanium (Ti) film, a 20 nm-thick titanium nitride (TiN) film and a 300 nm-thick tungsten (W) film are sequentially deposited by, e.g., CVD or sputtering, and then are removed by CMP or etching back until the surface of the inter-layer insulating film 50 is exposed to thereby leave these films selectively in the contact holes 52, 54, 56. Thus, plugs 58 buried in the contact holes 52, plugs 60 buried in the contact holes 54, and plugs 62 buried in the contact holes 56 are formed.

Thus, the nonvolatile semiconductor memory device according to the present embodiment can be fabricated.

As described above, according to the present embodiment, the bit line diffused layer on the bottom of the trench is formed, offset from the corner of the bottom of the trench, whereby the punch-through between the bit line diffused layers can be effectively prevented, and writing can be efficiently performed.

[A Second Embodiment]

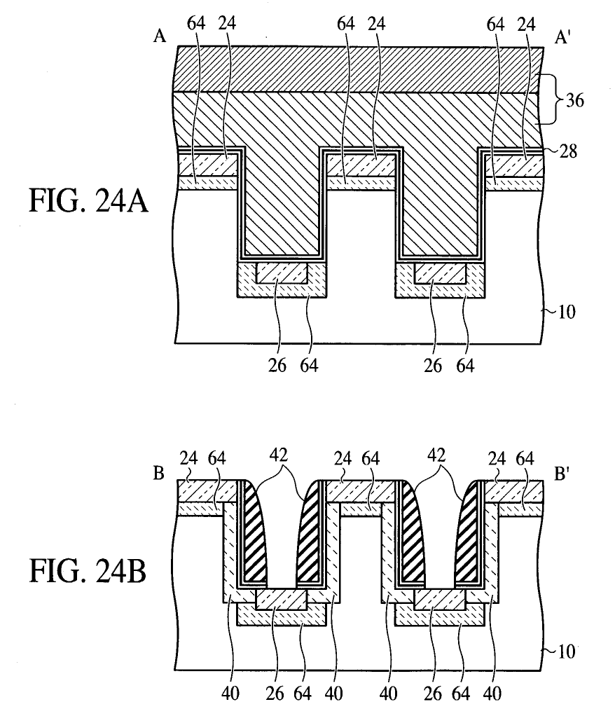

The nonvolatile semiconductor memory device and the method for fabricating the same according to a second embodiment of the present invention will be explained with reference to FIGS. 24A to 27C. The same members of the present embodiment as those of the nonvolatile semiconductor memory device and method for fabricating the same according to the first embodiment shown in FIGS. 1 to 23C are represented by the same reference numbers not to repeat or to simplify their explanation.

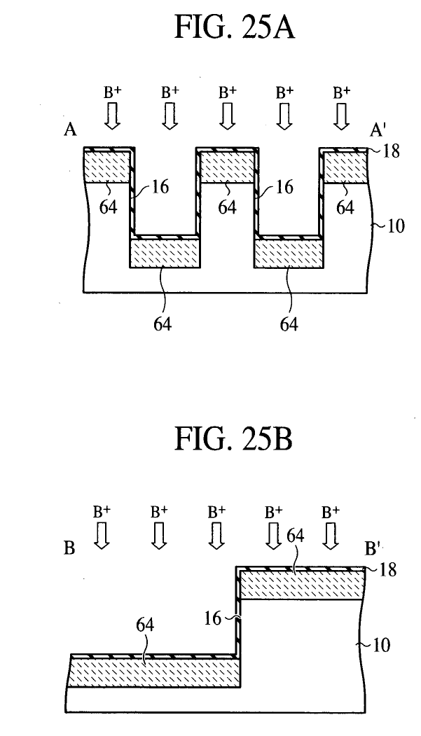

FIGS. 24A and 24B are diagrammatic sectional views of the nonvolatile semiconductor memory device according to the present embodiment, which show the structure thereof. FIGS. 25A-25B, 26A-26B, and 27A-27C are sectional views of the nonvolatile semiconductor memory device according to the present embodiment in the steps of the method for fabricating the same, which show the method.

First, the structure of the nonvolatile semiconductor memory device according to the present embodiment will be explained with reference to FIGS. 24A and 24B. FIG. 24A is the diagrammatic sectional view of the region corresponding to the section along the line A-A′ in FIG. 1. FIG. 24B is the sectional view of the region corresponding to the section along the line B-B′ in FIG. 1.

As shown in FIGS. 24A and 24B, the nonvolatile semiconductor memory device according to the present embodiment has the basic constitution which is the same as that of the nonvolatile semiconductor memory device according to the first embodiment shown in FIGS. 1 to 3. The nonvolatile semiconductor memory device according to the present embodiment is characterized mainly in that the nonvolatile semiconductor memory device according to the present embodiment further comprises a p-type impurity diffused layer 64 formed, surrounding bit line diffused layers 24, 26. The p-type impurity diffused layer 64 thus formed between the bit line diffused layer 24 and the bit line diffused layer 26 can further suppress the extension of the depletion layer between the bit line diffused layer 24 and the bit line diffused layer 26, and the punch-through immunity can be further increased.

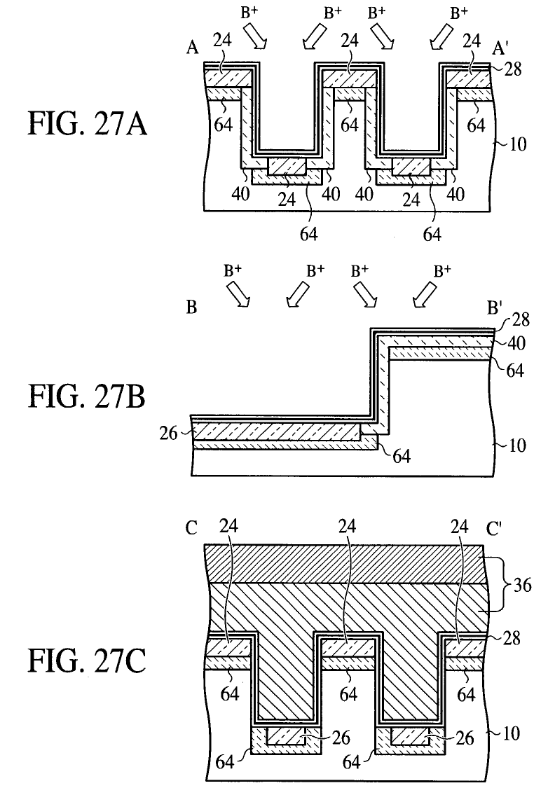

Then, the method for fabricating the nonvolatile semiconductor memory device according to the present embodiment will be explained with reference to FIGS. 25A to 27C. FIGS. 25A, 26A, and 27A are sectional views of the region corresponding to the section along the line A-A′ in FIG. 19. FIGS. 25B, 26B, and 27B are sectional views of the region corresponding to the section along the line B-B′ in FIG. 19. FIG. 27C is the sectional view of the region corresponding to the section along the line C-C′ in FIG. 19.

First, the trenches 16 are formed in a silicon substrate 10 in the same way as, e.g., in the method for fabricating the nonvolatile semiconductor memory device according to the first embodiment, which is shown in FIGS. 8, 9A and 9B.

Then, a silicon oxide film 18 of, e.g., a 5-20 nm-thick is formed in the trenches 16 by thermal oxidation at, e.g., 800-900° C.

Then, a photoresist film (not shown) covering a peripheral circuit region but exposing a memory cell region is formed by photolithography.

Next, with the photoresist film as a mask, boron ions, for example, are implanted at 20-40 keV acceleration energy, at a 0° tilt angle and to a dose of 1×10¹³-5×10¹³ cm⁻³ to form impurity diffused layers 64 on the surface of the silicon substrate 10 between the trenches 16 and on the bottoms of the trenches 16 (FIGS. 25A, and 25B). A width of the thus-formed impurity diffused layers 64 is recognized as being substantially equal to a width of the trenches 16.

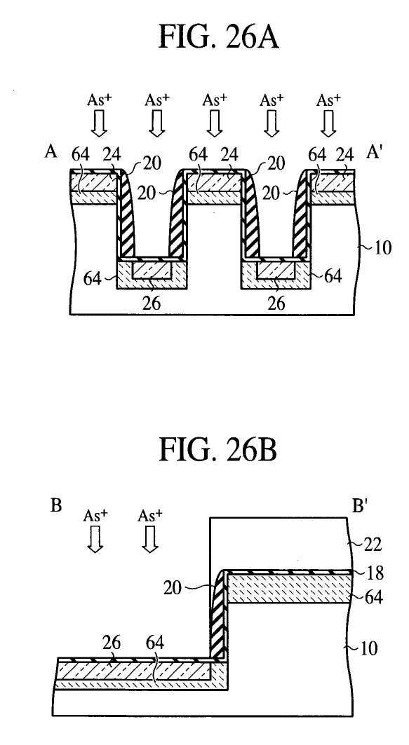

Then, in the same way as in, e.g., the method for fabricating the nonvolatile semiconductor memory device according to the first embodiment, which are shown in FIGS. 10 to 13B, the sidewall insulating film 20 of a silicon nitride film is formed on the sidewalls of the trenches 16, and a photoresist film 22 exposing the memory cell region is formed. Then, with the sidewall insulating film 20 and the photoresist film 22 as a mask, arsenic ions are implanted to form the bit line diffused layer 24 on the surface of the silicon substrate 10 in the regions between the adjacent trenches 16, and the bit line diffused layer 26 which is offset from the corners of the bottoms of the trenches 16 by a thickness of the sidewall insulating film 20 (FIGS. 26A and 26B).

Then, in the same way as in, e.g., the method for fabricating the nonvolatile semiconductor memory device according to the first embodiment, which is shown in FIGS. 14 to 18C, after the charge storage layer 28 and the word lines 36 have been formed, boron ions are implanted from two directions of 135° and 315° twist angles or 45° and 225° twist angles to the extending direction of the bit line diffused layers 24, 26 to form the channel cut diffused layer 40 between the bit line diffused layer 24 and the bit line diffused layer 26 in the regions between the word lines 36 (FIGS. 27A-27C).

Then, in the same was as in, e.g., the method for fabricating the nonvolatile semiconductor memory device according to the first embodiment, which is shown in FIGS. 19 to 23C, the sidewall insulating film 42, the inter-layer insulating film 50, the plugs 58, 62, etc. are formed.

Thus, the nonvolatile semiconductor memory device according to the present embodiment can be fabricated.

As described above, according to the present embodiment, the bit line diffused layer formed on the bottom of the trench is offset from the corner of the bottom of the trench, whereby the punch-through between the bit line diffused layers can be effectively prevented, and resultantly writing can be efficiently performed. The impurity diffused region of a conduction type opposite to that of the bit line diffused layers is formed surrounding the bit line diffused layers, whereby the extension of depletion layer between the bit line diffused layers can be further suppressed, and resultantly the punch-through immunity can be further improved.

[A Third Embodiment]

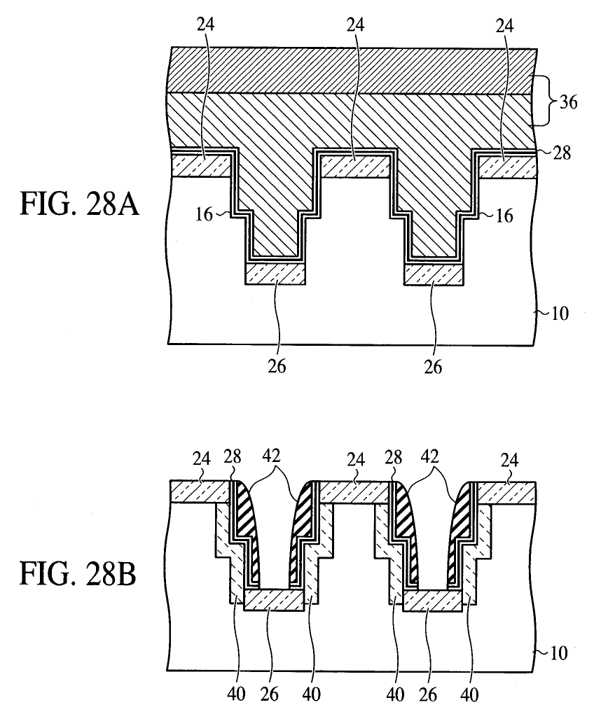

The nonvolatile semiconductor memory device and the method for fabricating the same according to a third embodiment of the present invention will be explained with reference to FIGS. 28A to 32B. The same members of the present embodiment as those of the nonvolatile semiconductor memory device and the method for fabricating the same according to the first and the second embodiments shown in FIGS. 1 to 27C are represented by the same reference numbers not to repeat or to simplify their explanation.

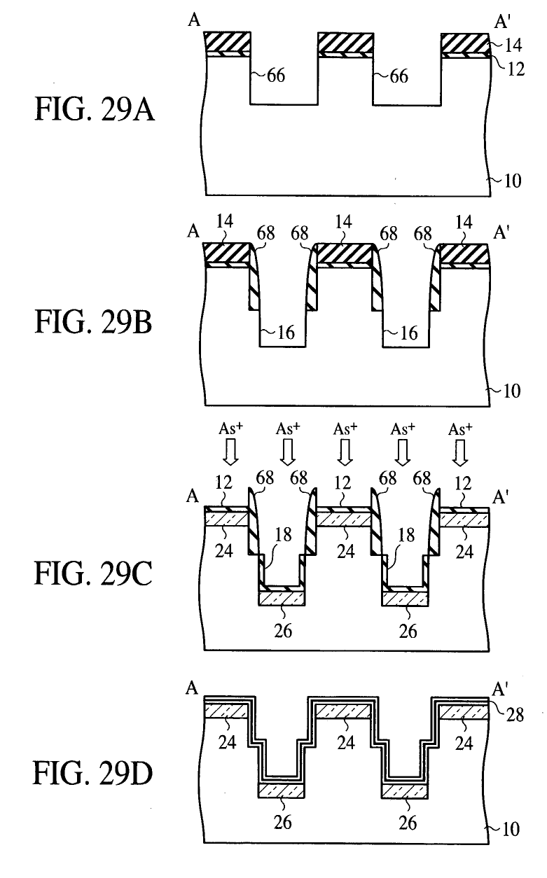

FIGS. 28A and 28B are diagrammatic sectional views of the nonvolatile semiconductor memory device according to the present embodiment, which show the structure thereof. FIGS. 29A-29D, 30A-30B, 31A-31B, and 32A-32B are sectional views of the nonvolatile semiconductor memory device according to the present embodiment in the steps of the method for fabricating the same, which show the method.

First, the structure of the nonvolatile semiconductor memory device according to the present embodiment will be explained with reference to FIGS. 28A and 28B. FIG. 28A is the sectional view of the region corresponding to the section along the line A-A′ in FIG. 1. FIG. 28B is the sectional view of the section corresponding to the section along the line B-B′ in FIG. 1.

As shown in FIGS. 28A and 28B, the nonvolatile semiconductor memory device according to the present embodiment has the basic constitution which is the same as that of the nonvolatile semiconductor memory device according to the first embodiment shown in FIGS. 1 to 3. The nonvolatile semiconductor device according to the present embodiment is characterized mainly in that the sidewalls of trenches 16 are stepped.

In the nonvolatile semiconductor memory device according to the first embodiment, the bit diffused layer 26 on the bottom of the trench 16 is offset from the corner of the bottom of the trench 16, whereby the punch-through between the bit line diffused layers 26, 28 is suppressed. In contrast to this, in the nonvolatile semiconductor memory device according to the present embodiment, the sidewalls of the trench 16 are formed in steps in place of forming the bit line diffused layer 26, offset from the corner of the bottom of the trench 16. Even in the case that the sidewalls of the trench 16 are formed in steps, the edge of the bit line diffused layer 26 is recognized as being offset from the corner of the bottom of the trench 16 as viewed from the regions of the trench 16 having a wider width. Accordingly, the sidewalls of the trench 16 are formed in steps, whereby the punch-through between the bit line diffused layers can be very effectively suppressed, as can be in the case that the bit line diffused layer of the bottom of the trench is offset from the corner of the bottom of the trench.

It is possible that the sidewalls of the trench 16 are formed in steps, and the bit line diffused layer on the bottom of the trench is offset from the corner of the bottom of the trench.

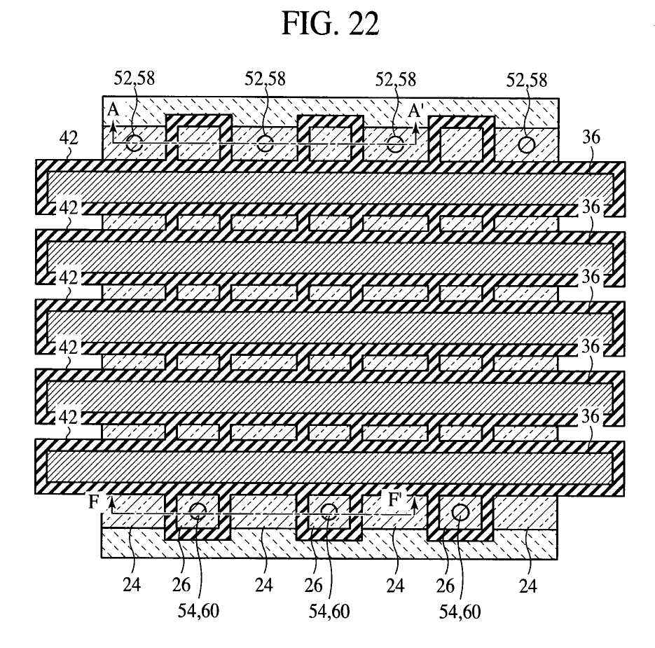

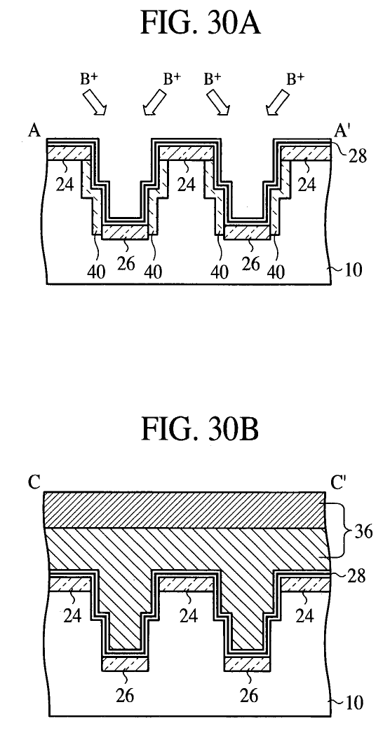

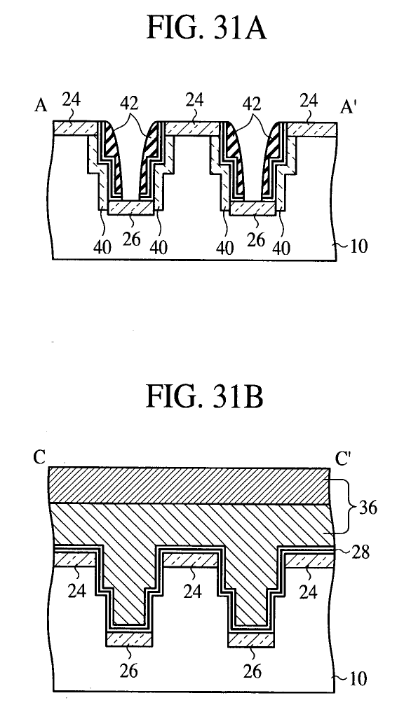

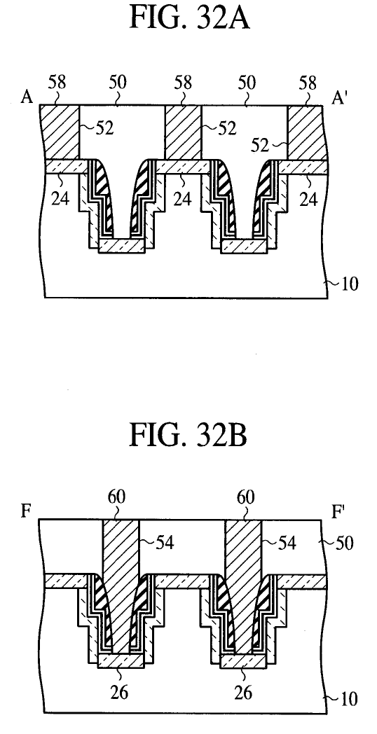

Then, the method for fabricating the nonvolatile semiconductor memory device according to the present embodiment will be explained with reference to FIGS. 29A to 32B. FIGS. 29A-29D, 31A, and 32A are sectional views of the region corresponding to the section along the line A-A′ in FIG. 19. FIGS. 30B and 31B are sectional views of the region corresponding to the section along the line C-C′ in FIG. 19. FIG. 32B is the sectional view of the region corresponding to the section along the line F-F′ in FIG. 22.

First, a 10-20 nm-thick silicon oxide film 12 is formed on a p-type silicon substrate 10 by thermal oxidation at, e.g., 900-950° C.

Then, a silicon nitride film 14 of, e.g., a 30-100 nm-thick is deposited on the silicon oxide film 12 by, e.g., CVD.

Then, the silicon nitride film 14, the silicon oxide film 12 and the silicon substrate 10 are etched by lithography and anisotropical etching to pattern the silicon nitride film 14 and the silicon oxide film 12 while forming 25-150 nm-depth trenches 66 in the silicon substrate 10 (FIG. 29A).

Next, a silicon oxide film of, e.g., a 50-150 nm-thick is deposited on the entire surface by, e.g., CVD and is anisotropically etched back to form the sidewall insulating film 68 of the silicon oxide film on the sidewalls of the trenches 66. The sidewall insulating film 68 may be formed of silicon nitride film.

Then, with the silicon nitride film 14 and the sidewall insulating film 68 as a mask, the silicon substrate 10 is anisotropically etched to form the trenches 16 of a 25-150 nm-depth in the bottoms of the trenches 66 (FIG. 29B). At this time, because of the sidewall insulating film 68 formed on the sidewalls of the trenches 66, a width of the trenches 16 becomes smaller by the thickness of the sidewall insulating film 68 than a width of the trenches 66. Thus, the sidewalls of the trenches formed in the silicon substrate 10 are stepped. In the following description, for the convenience, the trenches (the trenches 66 and the trenches 16) having the sidewalls stepped will be called the trenches 16 as a whole.

Next, a silicon oxide film 18, e.g., a 5-20 nm-thick is formed in the trenches 16 by thermal oxidation at, e.g., 800-900° C.

Then, the silicon nitride film 14 is removed by, e.g., wet etching using boiled phosphoric acid.

Then, a photoresist film (not shown) exposing the memory cell region is formed by photolithography. This photoresist film corresponds to the photoresist film 22 in FIGS. 12 and 13B.

Next, with the photoresist film as a mask, arsenic ions, for example, are implanted, for example, at 30-80 keV acceleration energy, at a 0° tilt angle, and to a dose of 1×10¹⁵-3×10^{15 cm}⁻² to form the bit line diffused layers 24 on the surface of the silicon substrate 10 in the regions between the adjacent trenches 16 and the bit line diffused layers 26 on the bottoms of the trenches 16 (FIG. 29C). A width of the thus formed bit line diffused layer 26 is recognized as being substantially equal to a width of the bottoms of the trenches 16.

Then, the silicon oxide films 12, 18 and the sidewall insulating film 68 are removed by, e.g., wet etching using an aqueous solution of hydrofluoric acid.

Next, in the same way as in, e.g., the method for fabricating the nonvolatile semiconductor memory device according to the first embodiment, a charge storage layer 28 of ONO film is formed (FIG. 29D).

Then, in the same way as in, e.g., the method for fabricating the nonvolatile semiconductor memory device according to the first embodiment, which is shown in FIGS. 14 to 18C, after the word lines 36 have been formed, boron ions are implanted from two directions of 135° and 315° twist angles or 45° and 225° twist angles to the extending direction of the bit line diffused layers 24, 26 to form the channel cut diffused layer 40 between the bit line diffused layer 24 and the bit line diffused layer 26 in the regions between the word lines 36 (FIGS. 30A and 30B).

Next, in the same was as in, e.g., the method for fabricating the nonvolatile semiconductor memory device according to the first embodiment shown in FIGS. 19 to 21C, the sidewall insulating film 42 of the silicon nitride film is formed on the sidewalls of the trenches 16 (FIGS. 31A and 31B).

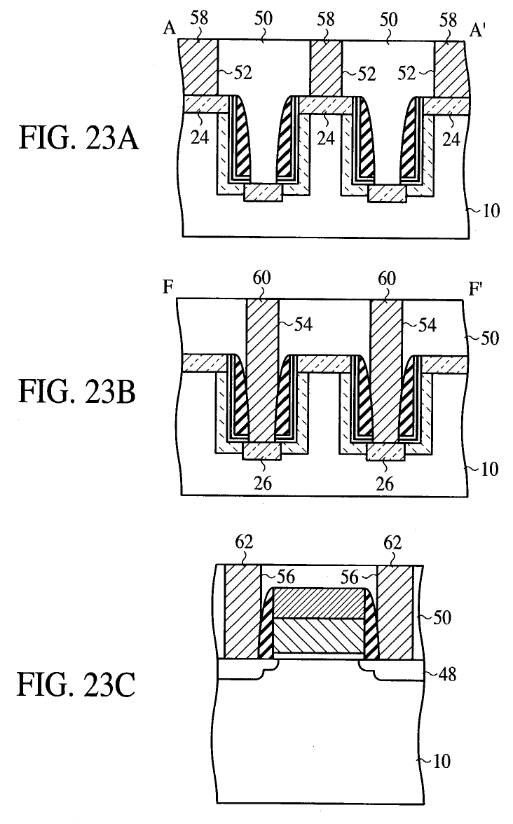

Then, in the same way as in, e.g., the nonvolatile semiconductor memory device according to the first embodiment shown in FIGS. 22 and 23A-23C, an inter-layer insulating film 50, plugs 58, 62, etc. are formed (FIGS. 32A and 32B).

Thus, the nonvolatile semiconductor memory device according to the present embodiment can be fabricated.

As described above, according to the present embodiment, the sidewalls of the trench are stepped to form the bit line diffused layer on the bottom of the trench, offset from the corner of the bottom of the trench, whereby the punch-through between the bit line diffused layers can be effectively prevented, and resultantly writing can be efficiently performed. The impurity diffused region of a conduction type opposite to that of the bit line diffused layers is formed, surrounding the bit line diffused layers, whereby the extension of the depletion layer between the bit line diffused layers can be further suppressed, and resultantly the punch-through immunity can be further improved.

[A Fourth Embodiment]

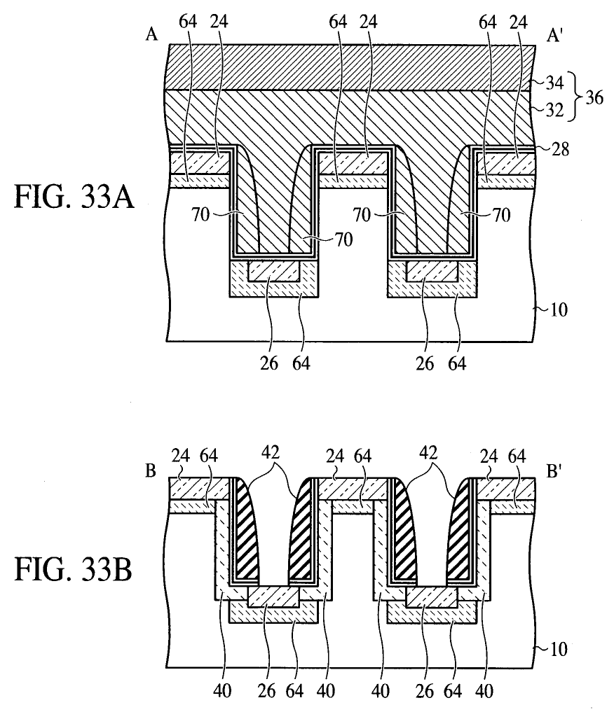

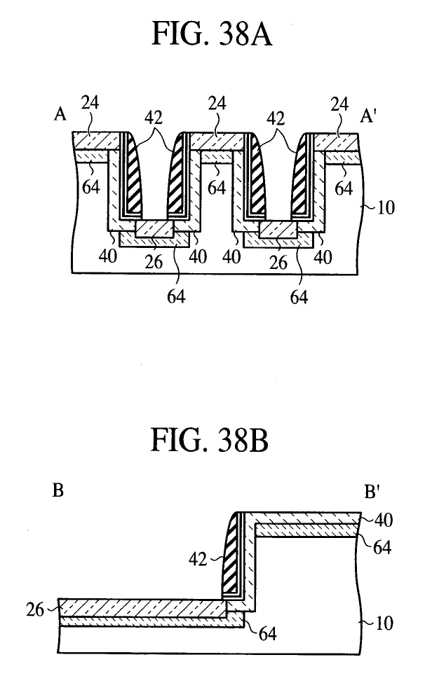

The nonvolatile semiconductor memory device and the method for fabricating the same according to a fourth embodiment of the present invention will be explained with reference to FIGS. 33A to 38B. The same members of the present embodiment as those of the nonvolatile semiconductor memory device and method for fabricating the same according to the first to the third embodiments shown in FIGS. 1 to 32B are represented by the same reference numbers not to repeat or to simplify their explanation.

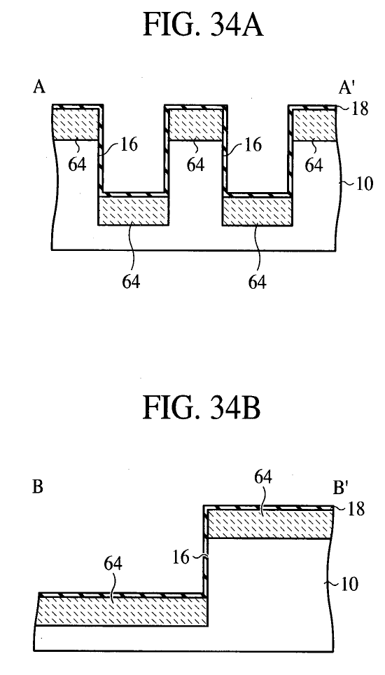

FIGS. 33A and 33B are diagrammatic sectional views of the nonvolatile semiconductor memory device according to the present embodiment, which show the structure thereof. FIGS. 34A to 38B are sectional views of the nonvolatile semiconductor memory device according to the present embodiment in the steps of the method for fabricating the same, which show the method.

First, the structure of the nonvolatile semiconductor memory device according to the present embodiment will be explained with reference to FIGS. 33A and 33B. FIG. 33A is a sectional view of the region corresponding to the section along the line A-A′ in FIG. 1. FIG. 33B is the sectional view of the region corresponding to the section along the line B-B′ in FIG. 1.

As shown in FIGS. 33A and 33B, the nonvolatile semiconductor memory device according to the present embodiment has the basic constitution which is the same as that of the nonvolatile semiconductor memory device according to the second embodiment shown in FIGS. 24A and 24B. The nonvolatile semiconductor memory device according to the present embodiment is characterized mainly in that word lines 36 are formed of a sidewall conducting film 70 of an amorphous silicon film formed on the sidewalls of trenches 16 with a charge storage layer 28 formed in, an amorphous silicon film 32, and a tungsten silicide film 34. The nonvolatile semiconductor memory device is thus constituted, whereby it is not necessary to remove the sidewall film (the sidewall conducting film 70) used in offsetting the bit line diffused layer 16 from the corners of the bottoms of the trenches 16. The fabrication steps can be accordingly simplified.

Then, the method for fabricating the nonvolatile semiconductor memory device according to the present embodiment will be explained with reference to FIGS. 34A to 38B. FIGS. 34A, 35A, 36A, 37A and 38A are the sectional views of the region corresponding to the section along the line A-A′ in FIG. 19. FIGS. 34B, 35B, 36B, 37B, and 38B are sectional views of the region corresponding to the section along the line B-B′ in FIG. 19. FIGS. 34C, 35C, 36C, 37C, and 38C are the sectional views of the region corresponding to the section along the line C-C′ in FIG. 22.

First, in the same way as in, e.g., the method for fabricating the nonvolatile semiconductor memory device according to the first embodiment shown in FIGS. 8, 9A, and 9B, the trenches 16 are formed in the silicon substrate 10.

Next, in the same way as in, e.g., the method for fabricating the nonvolatile semiconductor memory device according to the first embodiment, the silicon oxide film 18 and the impurity diffused layers 64 are formed (FIGS. 34A and 34B).

Next, in the same way as in, e.g., the method for fabricating the nonvolatile semiconductor memory device according to the first embodiment, the charge storage layer 28 of the ONO film is formed. The charge storage layer 28 may be formed before the formation of the impurity diffused layers 64.

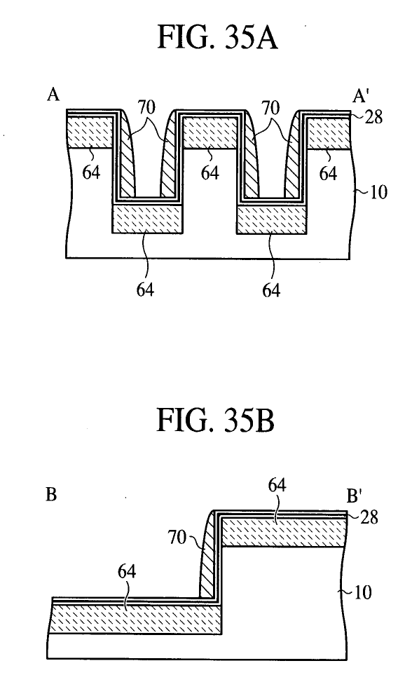

Next, a 50-150 nm-thick amorphous silicon film doped with a 2×10²⁰-3×10²¹ cm⁻³ concentration of phosphorus is deposited by, e.g., CVD and is anisotropically etched back to form the sidewall conducting film 70 of the amorphous silicon film on the sidewalls of the trenches 16 with the charge storage layer 28 formed on (FIGS. 35A and 35B).

Then, a photoresist film 22 covering a peripheral circuit region and exposing a memory cell region is formed by photolithography.

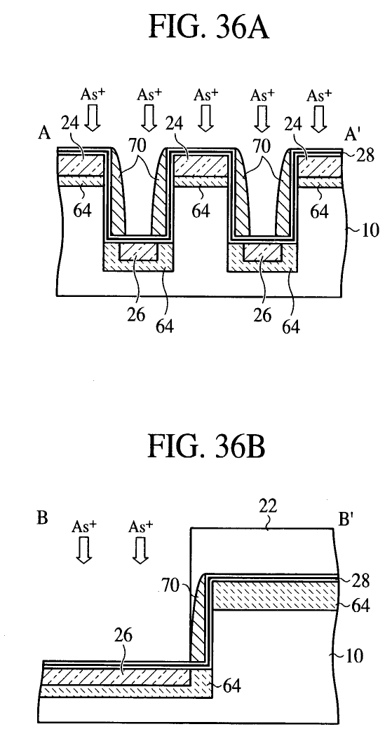

Next, with the photoresist film 22 as a mask, arsenic ions, for example, are implanted at 30-80 keV acceleration energy, at a 0° tilt angle, and to a dose of 1×10¹⁵-3×10¹⁵ cm⁻² to form the bit line diffused layer 24 on the surface of the silicon substrate 10 in the regions between the adjacent trenches 16, and the bit line diffused layer 26 on the bottoms of the trenches 16, offset from the corners of the bottoms of the trenches 16 by a thickness of the sidewall conducting film 70 (FIGS. 36A and 36B).

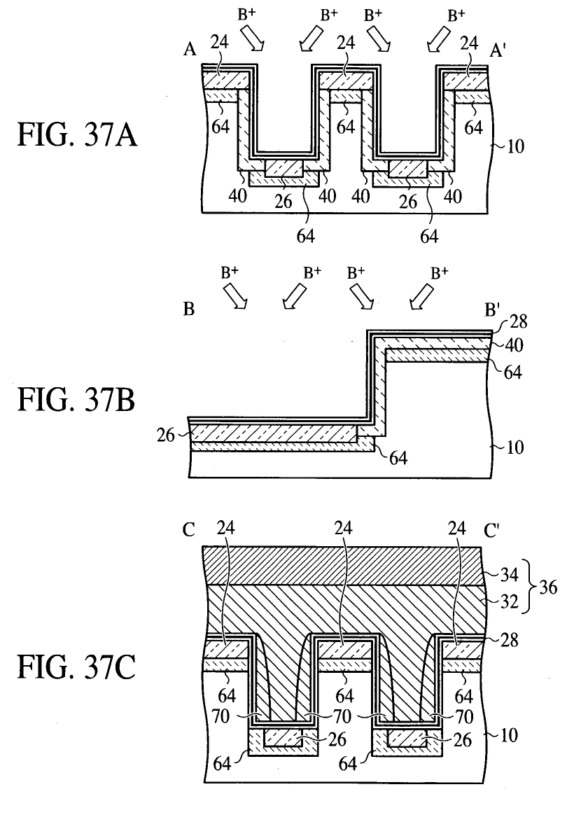

Next, in the same way as in, e.g., the method for fabricating the nonvolatile semiconductor memory device according to the first embodiment shown in FIGS. 16 to 18C, the word lines 36 and a channel cut diffused layer 40 are formed. At this time, the sidewall conducting film 70 of the amorphous silicon film forms a part of the word lines 36 together with the amorphous silicon film 32 and the tungsten silicide film 34 (FIGS. 37A and 37B).

Then, in the same way as in, e.g., the method for fabricating the nonvolatile semiconductor memory device according to the first embodiment shown in FIGS. 19 to 21C, a sidewall insulating film 42 of a silicon nitride film is formed on the sidewalls of the trenches 16 (FIGS. 37A and 37B).

Next, in the same way as in, e.g., the method for fabricating the nonvolatile semiconductor memory device according to the first embodiment shown in FIGS. 22 and 23A-23C, the inter-layer insulating film 50, plugs 58, 62, etc. are formed.

Thus, the nonvolatile semiconductor memory device according to the present embodiment can be fabricated.

As described above, according to the present embodiment, the bit line diffused layer on the bottom of the trench is offset from the corner of the bottom of the trench, whereby the punch-through between the bit line diffused layers can be effectively prevented, and resultantly writing can be efficiently performed. The impurity diffused region of a conduction type opposite to that of the bit line diffused layer is formed, surrounding the bit line diffused layers, whereby the extension of the depletion layer between the bit line diffused layers can be further suppressed, and the punch-through immunity can be further improved. The sidewall film used in forming the bit line diffused layer is used as a part of the word lines, which can simplify the fabrication steps.

[A Fifth Embodiment]

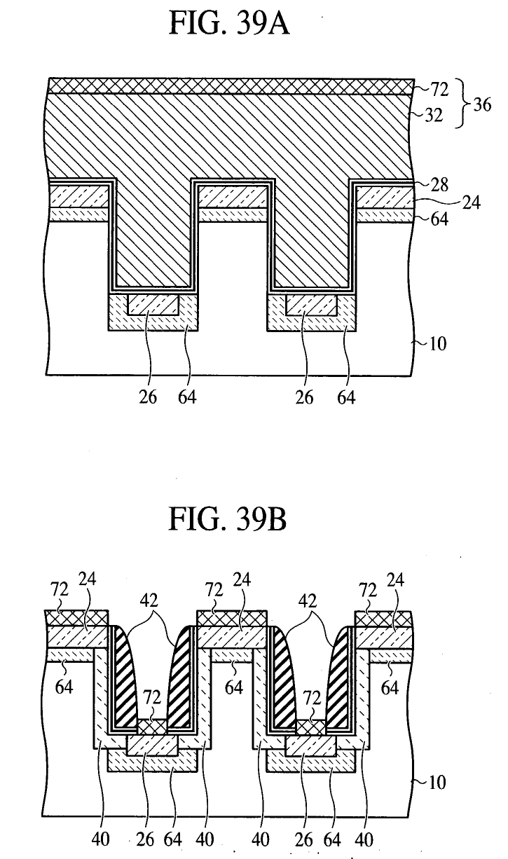

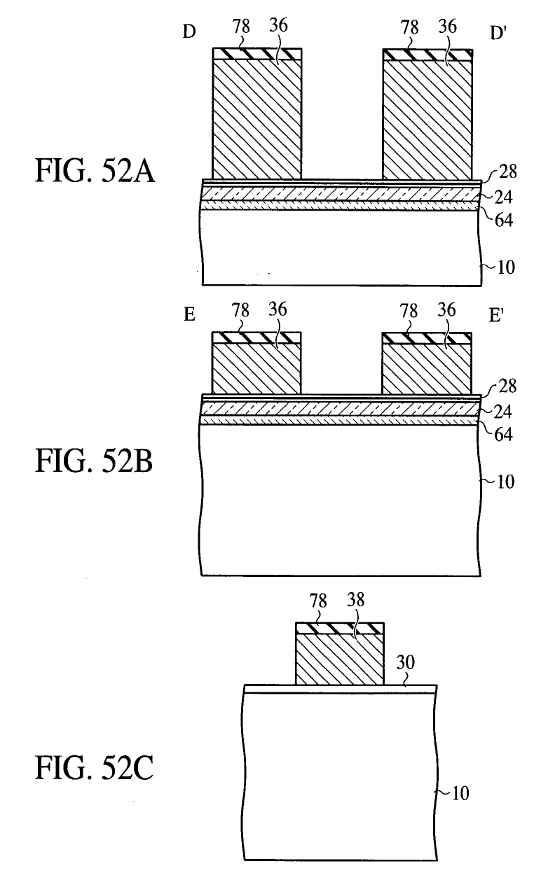

The nonvolatile semiconductor memory device and the method for fabricating the same according to a fifth embodiment of the present invention will be explained with reference to FIGS. 39A to 57C. The same members of the present embodiment as those of the nonvolatile semiconductor memory device and the method for fabricating the same according to the first to the fourth embodiments shown in FIGS. 1 to 38B are represented by the same reference numbers not to repeat or to simplify their explanation.

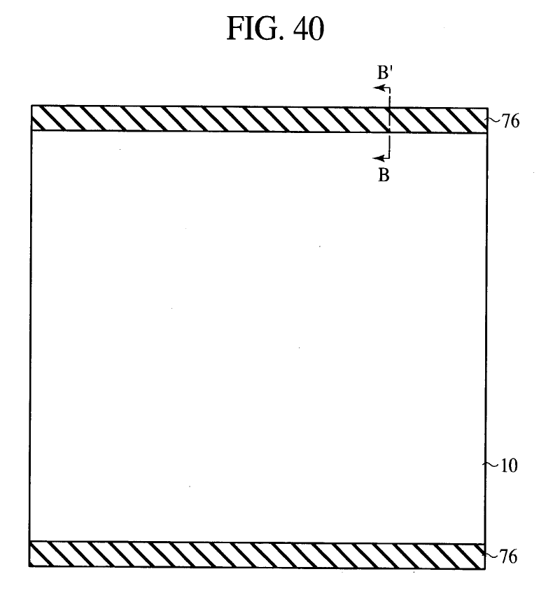

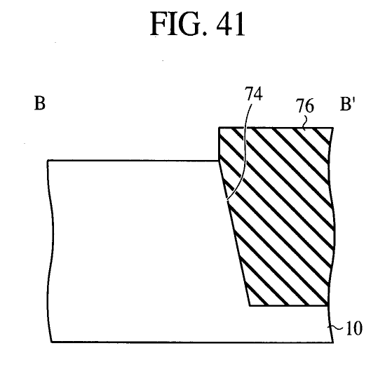

FIGS. 39A and 39B are diagrammatic sectional views of the nonvolatile semiconductor memory device according to the present embodiment, which show the structure thereof. FIGS. 40, 42, 44, 46, 48, 50, 53 and 56 are plan views of the nonvolatile semiconductor memory device according to the present embodiment in the step of the method for fabricating the same, which show the method. FIGS. 41, 43A-43B, 45A-45B, 47A-47B, 49A-49B, 51A-51C, 52A-52C, 54A-54C, 55A-55C, and 57A-57C are sectional views of the nonvolatile semiconductor memory device according to the present embodiment in the steps of the method for fabricating the same, which show the method.

First, the structure of the nonvolatile semiconductor memory device according to the present embodiment will be explained with reference to FIGS. 39A and 39B. FIG. 39A is the sectional view of the region corresponding to the section along the line A-A′ in FIG. 1. FIG. 39B is the sectional view of the region corresponding to the section along the line B-B′ in FIG. 1.

As shown in FIGS. 39A and 39B, the nonvolatile semiconductor memory device according to the present embodiment basically has the same structure as that of the nonvolatile semiconductor memory device according to the second embodiment shown in FIGS. 24A and 24B. The nonvolatile semiconductor memory device according to the present embodiment is characterized mainly in that a so-called salicide (self-aligned silicide) process is used in the fabrication process, and a cobalt silicide film 72 is formed selectively on the bit line diffused layers 24, 26. The Word lines 36 have the polycide structure of a layer film of an amorphous silicon film 32 and a cobalt silicide film 72. The use of the salicide process much decreases the resistance of the bit line diffused layers 24, 26, which much contributes to high-speed operation.

Next, the method for fabricating the nonvolatile semiconductor memory device according to the present embodiment will be explained with reference to FIGS. 40 to 57C.

First, a device isolation film 76 is formed on a p-type silicon substrate 10 by, e.g., STI (shallow trench isolation) method, buried in trenches 74 (FIGS. 40 and 41). A 10-20 nm-thick silicon oxide film (not shown) is formed by thermal oxidation at, e.g., 900-950° C., and a 100-150 nm-thick silicon nitride film (not shown) is formed by CVD. Then, the silicon nitride film, the silicon oxide film and the silicon substrate 10 are etched by photolithography and anisotropical etching to pattern the silicon nitride film and the silicon oxide film while forming the trenches 74 of, e.g., a 200-400 nm-depth in the silicon substrate 10. Next, a 500 nm-thick silicon oxide film is deposited by, e.g., CVD and then is removed plainly by CMP until the surface of the silicon nitride film is exposed, and the device isolation film 76 is formed, buried in the trenches 74.

As shown in FIG. 40, the device isolation film 76 in a memory cell region is formed in strips at least on the upper end and the lower end of the memory cell region. This is because when the cobalt silicide film 72 is formed on the bit line diffused layer 24, the cobalt silicide film 72 is prohibited from short-circuiting with the adjacent bit line diffused layer 24. It is possible to form the device isolation film 76 concurrently with the formation of an device isolation film (not shown) for a peripheral circuit region.

Then, a 10-20 nm-thick silicon oxide film 12 is formed on the silicon substrate 10 with the device isolation film 76 formed on by thermal oxidation at, e.g., 900-950° C.

Then, a silicon nitride film 14 of, e.g., a 100-150 nm-thick is formed on the silicon oxide film 12 by, e.g., CVD.

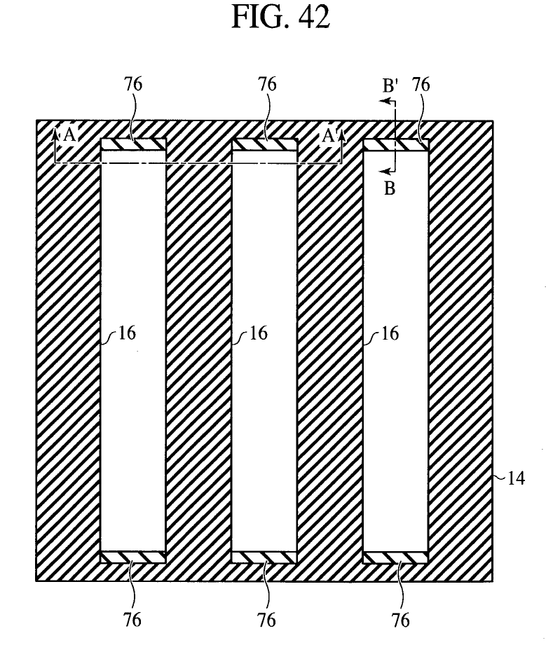

Next, the silicon nitride film 14 and the silicon oxide film 12 are patterned by photolithography and anisotropical etching. At this time, as shown in FIG. 42, the silicon nitride film 14 and the silicon oxide film 12 are patterned to have striped openings the upper and the lower ends of which are positioned on the device isolation film 76.

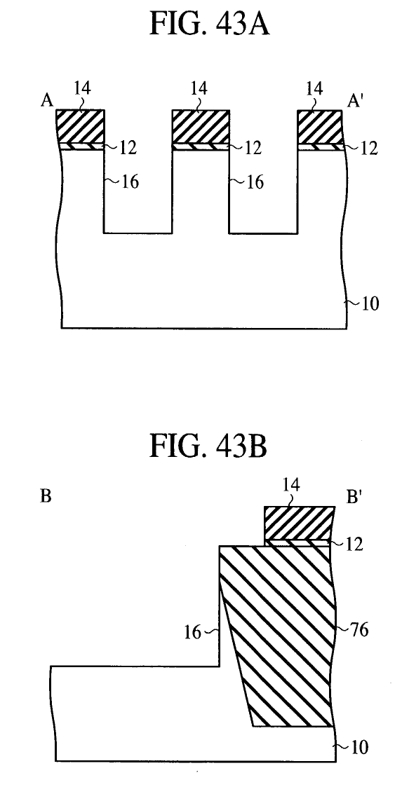

Next, with the silicon nitride film 14 and the device isolation film 76 as a mask, the silicon substrate 10 is anisotropically etched to form the trenches 16 of, e.g., a 50-300 nm-depth in the silicon substrate 10 (FIGS. 42, 43A, and 43B).

Then, in the same way as in, e.g., the method for fabricating the nonvolatile semiconductor memory device according to the second embodiment shown in FIGS. 25A and 25B, the impurity diffused layers 64 are formed on the surface of the silicon substrate 10 in the regions between the trenches 16 and on the bottoms of the trenches 16.

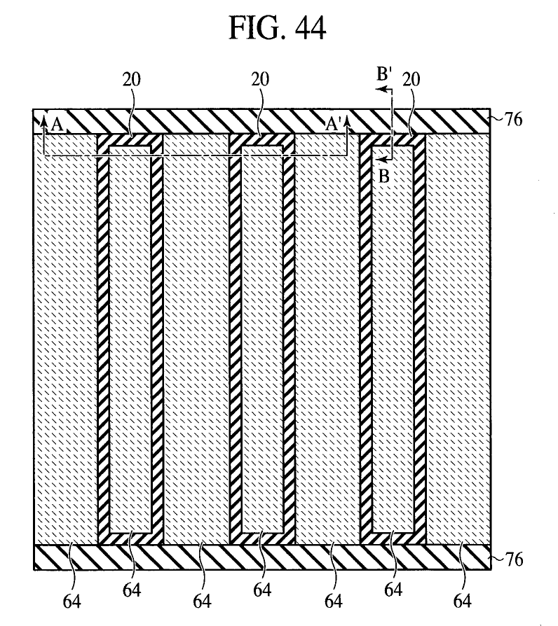

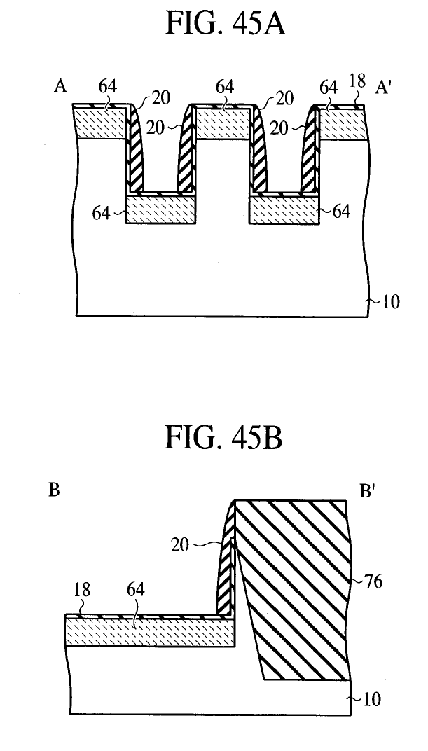

Next, in the same way as in, e.g., the method for fabricating the nonvolatile semiconductor memory device according to the first embodiment shown in FIGS. 10, 11A, and 11B, the silicon oxide film 18 formed on the surface of the silicon substrate, and the sidewall insulating film 20 formed of the silicon nitride film formed on the sidewalls of the trenches 16 are formed (FIGS. 44, 45A, and 45B).

Then, a photoresist film (not shown) exposing the memory cell region is formed by photolithography.

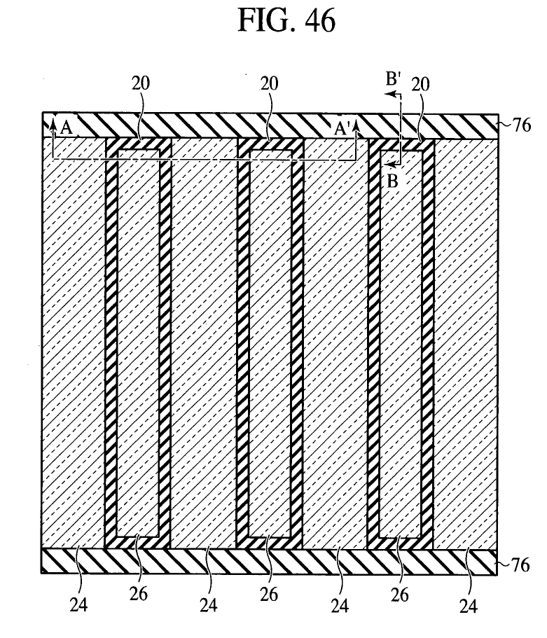

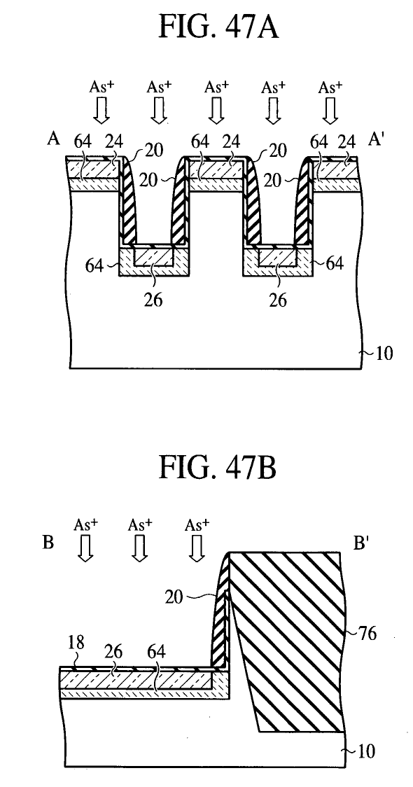

Next, with the photoresist film as a mask, arsenic ions, for example, are implanted, for example, at 30-80 keV acceleration energy, and to a dose of 1×10¹⁵-3×10¹⁵ cm⁻² to form the bit line diffused layer 24 on the surface of the silicon substrate 10 in the regions between the adjacent trenches 16 and the bit line diffused layer 26 on the bottoms of the trenches 16, offset from the corners of the bottoms of the trenches 16 by a thickness of the sidewall insulating film 20 (FIGS. 46, 47A, and 47B).

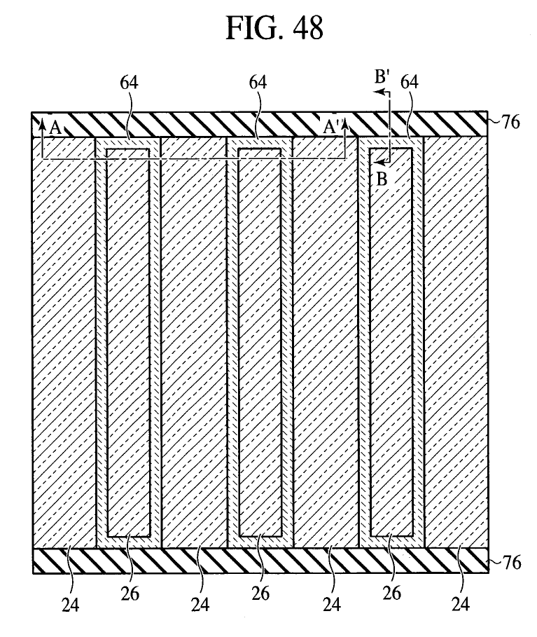

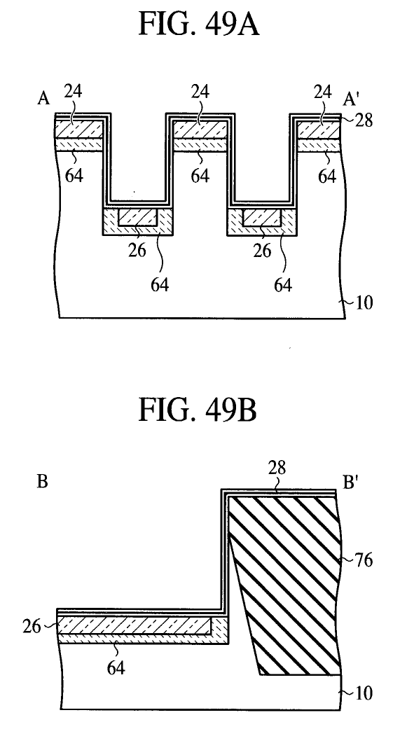

Next, in the same way as in, e.g., the method for fabricating the nonvolatile semiconductor memory device according to the first embodiment shown in FIGS. 14, 15A, and 15B, the sidewall insulating film 20 and the silicon oxide film 18 are removed, and then a charge storage layer 28 of the ONO film is formed (FIGS. 48, 49A, and 49B).

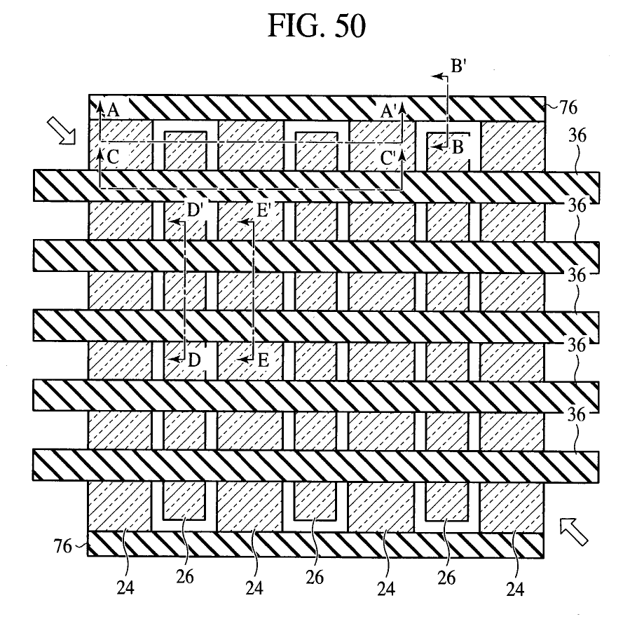

Then, e.g., a 100-200 nm-thick amorphous silicon film doped with, e.g., a 2×10²⁰-3×10²¹ cm⁻³ concentration of phosphorus, and, e.g., a 20-30 nm-thick silicon oxide film 78 are deposited on the entire surface by, e.g., CVD Next, the silicon oxide film 78 and the amorphous silicon film 32 are patterned by photolithography and anisotropical etching to form the word lines 36 and the gate electrodes 38 of the peripheral circuit transistors formed of the amorphous silicon film 32 and having the upper surfaces covered with the silicon oxide film 78 (FIGS. 50, 51C, and 52A-52C).

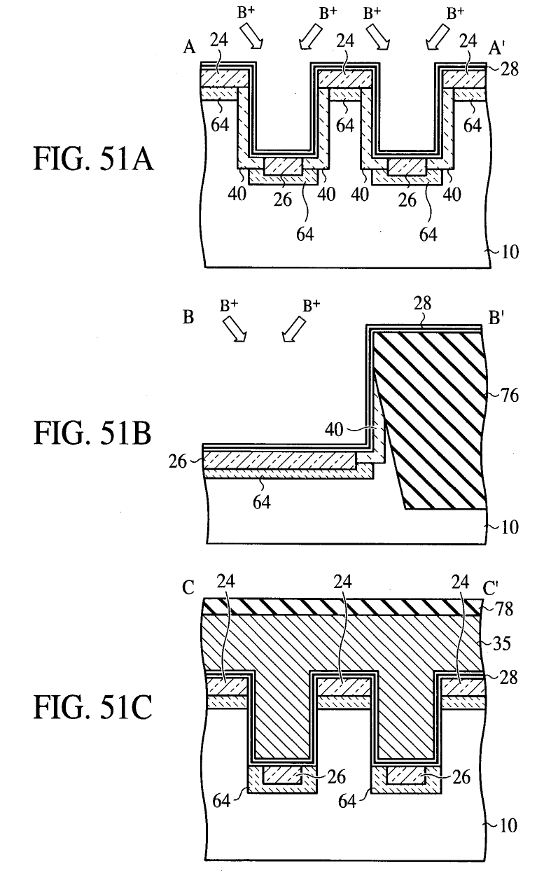

Then, in the same way as in, e.g., the method for fabricating the nonvolatile semiconductor memory device according to the first embodiment shown in FIGS. 17A and 17B, boron ions are implanted from two directions of 135° and 315° twist angles or 45° and 225° twist angles to the extending direction of the bit line diffused layers 24, 26 to form the channel cut diffused layers 40 between the bit line diffused layers 24 and the bit line diffused layers 26 in the regions between the word lines 36 (FIGS. 51A and 51B).

Next, a silicon nitride film of, e.g., a 50-150 nm-thick is deposited on the entire surface by, e.g., CVD and is anisotropically etched back to form the sidewall insulating film 42 on the sidewalls of the trenches 16, the word lines 36 and the gate electrodes 38.

Next, the silicon oxide film 78 formed on the word lines 36 and the gate electrodes 38, and the silicon oxide film (not shown) formed on the bit line diffused layers 24, 26 and the source/drain diffused layers 48 are removed by, e.g., wet etching using, e.g., an aqueous solution of hydrofluoric acid.

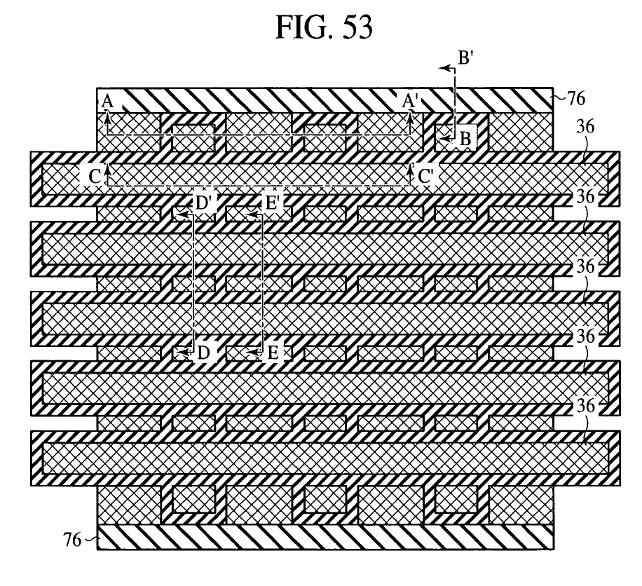

Then, the cobalt silicide film 72 is formed by salicide process selectively on the bit line diffused layers 24, 26, on the word lines 36, the gate electrodes 38 and the source/drain diffused layers 48 (FIGS. 53-55C). For example, first a 5-10 nm-thick cobalt (Co) film and a 20-50 nm-thick titanium nitride (TiN) film are deposited by sputtering. Next, rapid thermal annealing (RTA) at, e.g., 450-550° C. is performed to react the cobalt film with silicon in the regions where the silicon is exposed on the base to thereby form the cobalt silicide film 72 in the regions. Then, the titanium nitride film and the cobalt film which remains not reacted are removed. Thus, the cobalt silicide film 72 is left selectively on the bit line diffused layers 24, 26, on the word lines 36, on the gate electrodes 38 and on the source/drain diffused layers 48.

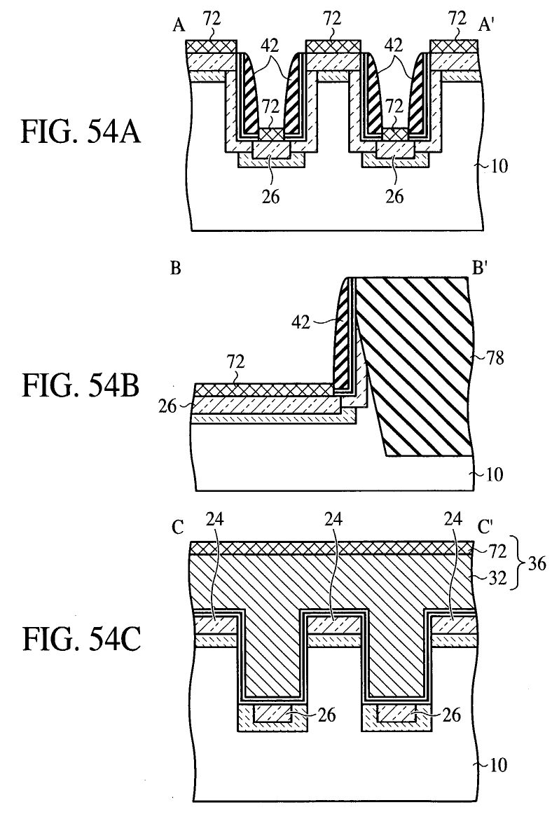

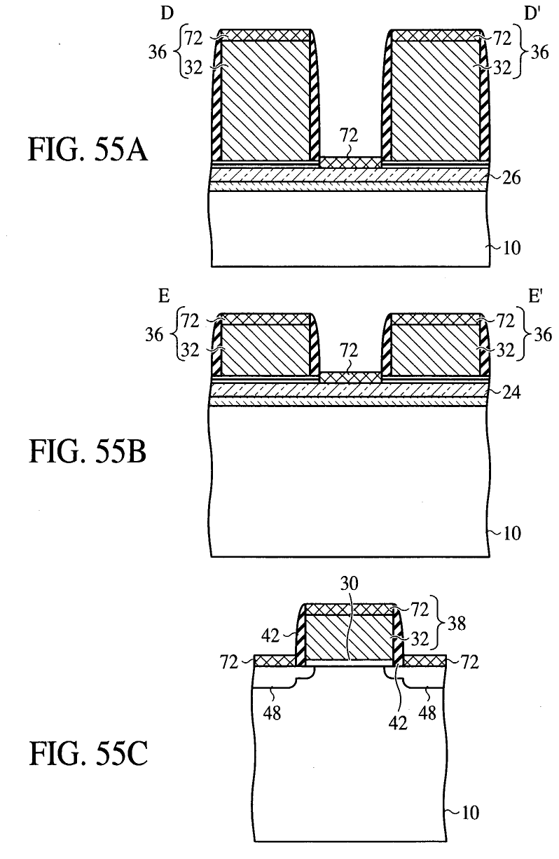

Thus, the word lines 36 and the gate electrodes 38 have the polycide gate structure formed of the layer film of the amorphous silicon film 32 and the cobalt silicide film 72 (FIGS. 54C, and 55A-55C).

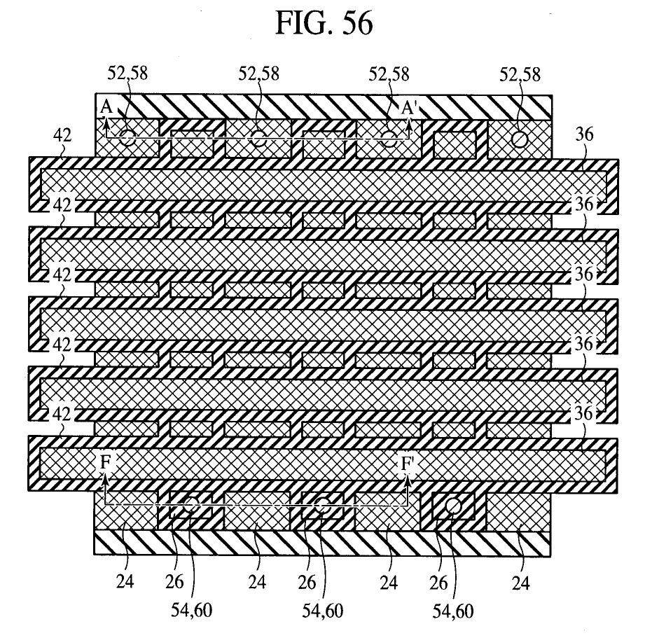

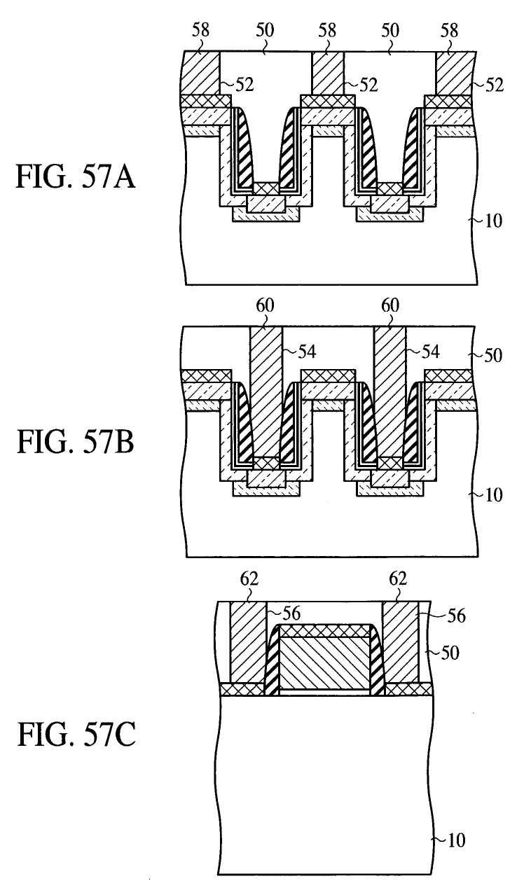

Next, in the same way as in, e.g., the method for fabricating the nonvolatile semiconductor memory device according to the first embodiment shown in FIGS. 22 and 23A-23C, the inter-layer insulating film 50, plugs 58, 62, 64, etc. are formed (FIGS. 56, and 57A-57C).

Thus, the nonvolatile semiconductor memory device according to the present embodiment can be fabricated.

As described above, according to the present embodiment, the bit line diffused layer on the bottom of the trench is formed, offset from the corner of the bottom of the trench, whereby the punch-through between the bit line diffused layers can be effectively prevented, and resultantly writing can be efficiently performed. The impurity diffused layer of a conduction type opposite to that of the bit line diffused layers is formed, surrounding the bit line diffused layers, whereby the extension of depletion layer between the bit line diffused layers can be further suppressed, and resultantly the punch-through immunity can be further improved. The silicide film is formed by salicide process selectively on the bit line diffused layers, whereby the bit line diffused layer resistance can be drastically decreased.

[A Sixth Embodiment]

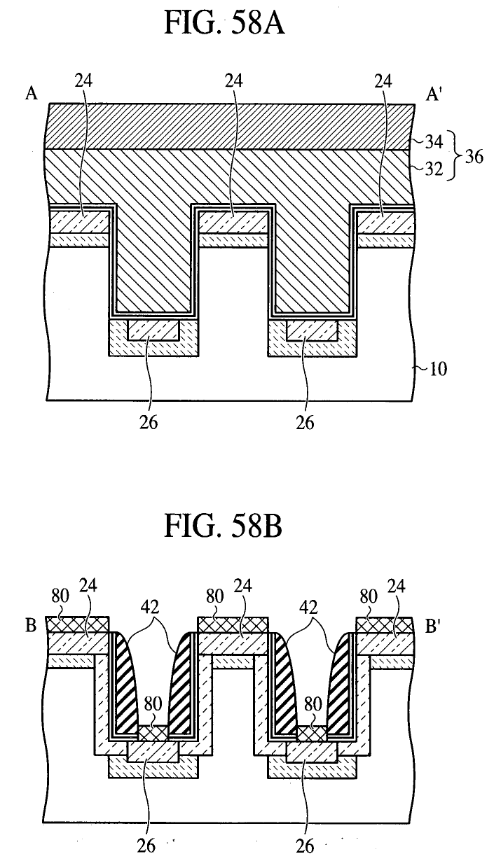

The nonvolatile semiconductor memory device and the method for fabricating the same according to a sixth embodiment of the present invention will be explained with reference to FIGS. 58 to 60C. The same members of the present embodiment as those of the nonvolatile semiconductor memory device and the method for fabricating the same according to the first to the fifth embodiments shown in FIGS. 1 to 57C are represented by the same reference numbers not to repeat or to simplify their explanation.

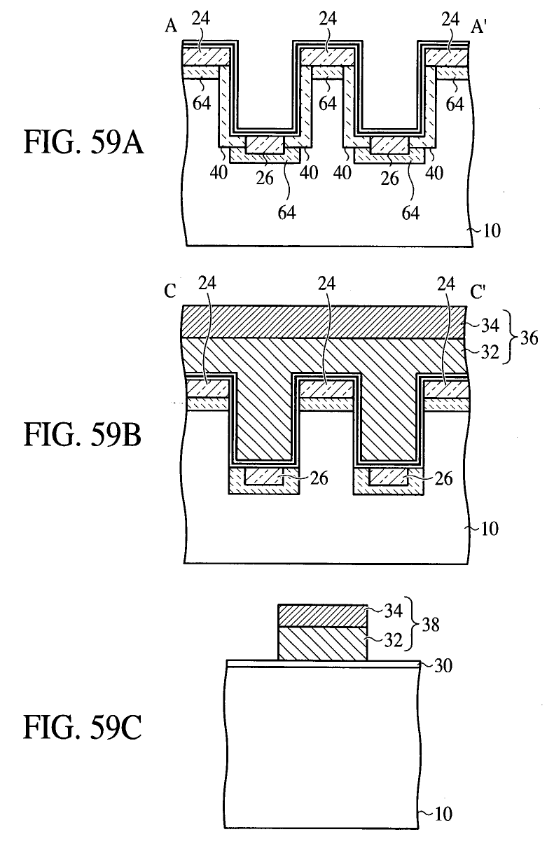

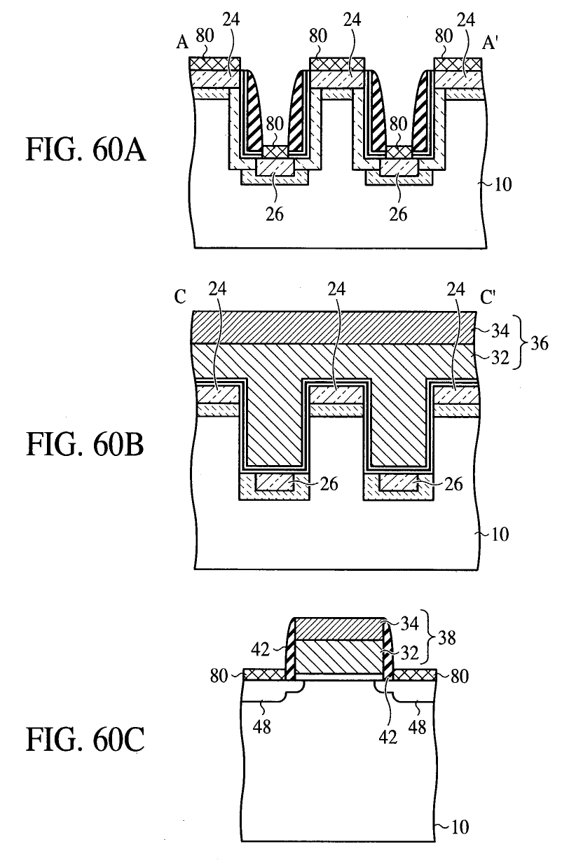

FIGS. 58A and 58B are diagrammatic sectional views of the nonvolatile semiconductor memory device according to the present embodiment, which show the structure thereof. FIGS. 59A-59C and 60A-60C are sectional views of the nonvolatile semiconductor memory device according to the present embodiment in the steps of the method for fabricating the same, which show the method.

First, the structure of the nonvolatile semiconductor memory device according to the present embodiment will be explained with reference to FIGS. 58A and 58B. FIG. 58A is the sectional view of the region corresponding to the section along the line A-A′ in FIG. 1. FIG. 58B is the sectional view of the region corresponding to the section along the line B-B′ in FIG. 1.

As shown in FIGS. 58A and 58B, the nonvolatile semiconductor memory device according to the present embodiment basically has the same structure as that of the nonvolatile semiconductor memory device according to the second embodiment shown in FIGS. 24A and 24B. The nonvolatile semiconductor memory device according to the present embodiment is characterized mainly in that a titanium silicide film 80 is formed on the bit line diffused layers 24, 26 by self-alignment. The nonvolatile semiconductor memory device of such constitution can much reduce the resistance of the bit line diffused layers 24, 26, which contributes to the high speed operation, as can the nonvolatile semiconductor memory device according to the fifth embodiment.

Next, the method for fabricating the nonvolatile semiconductor memory device according to the present embodiment will be explained with reference to FIGS. 59A-59C and 60A-60C. FIGS. 59A and 60A are the sectional views of the region corresponding to the section along the line A-A′ in FIG. 50. FIGS. 59B and 60B are the sectional views of the region corresponding to the section along the line B-B′ in FIG. 50.

First, in the same way as in, e.g., the method for fabricating the nonvolatile semiconductor memory device according to the fifth embodiment shown in FIGS. 40 to 49B, the trenches 16, the bit line diffused layers 24, 26, the charge storage layer 28, the impurity diffused layers 64, etc. are formed on the silicon substrate 10.

Next, in the same way as in, e.g., the method for fabricating the nonvolatile semiconductor memory device according to the fifth embodiment shown in FIGS. 14 to 18C, after the word lines 36 have been formed, boron ions are implanted from two directions of 135° and 315° twist angles or 45° and 225° twist angles to the extending direction of the bit line diffused layers 24, 26 to form the channel cut diffused layers 40 between the bit line diffused layers 24 and the bit line diffused layers 26 in the regions between the word lines 36 (FIGS. 59A and 59B).

The gate electrodes 38 of peripheral circuit transistors have the polycide gate structure formed of the layer film of an amorphous silicon film 32 and a tungsten silicide film 34, as are the word lines 36 (FIG. 59C).

Next, a silicon nitride film of, e.g. a 50-150 nm-thick is deposited on the entire surface by, e.g., CVD and is anisotropically etched back to form the sidewall insulating film 42 of the silicon nitride film on the side walls of the trenches 16, the word lines 36 and the gate electrodes 38.

A silicon oxide film (not shown) formed on the bit line diffused layers 24, 26 and the source/drain diffused layers 48 is removed by wet etching using, e.g., an aqueous solution of hydrofluoric acid.

Next, the titanium silicide film 80 is formed by silicide process selectively on the bit line diffused layers 24, 26 and the source/drain diffused layers 48 (FIGS. 60A to 60C). For example, a 20-50 nm-thick titanium (Ti) film is deposited by sputtering. Then, rapid thermal annealing at, e.g., 650-750° C. is performed to react the titanium film with the silicon in the regions where the silicon is exposed on the base to thereby form the titanium silicide film 80 in the regions. Next, the titanium film left not reacted is removed. Thus, the titanium silicide film 80 is left selectively on the bit line diffused layers 24, 26 and the source/drain diffused layers 48.

Then, in the same way as in, e.g., the method for fabricating the nonvolatile semiconductor memory device according to the first embodiment shown in FIGS. 22 and 23A-23C, the inter-layer insulating film 50, the plugs 58, 62, 64, etc. are formed.

Thus, the nonvolatile semiconductor memory device according to the present embodiment can be fabricated.

As described above, according to the present embodiment, the bit line diffused layer on the bottom of the trench is formed, offset from the corner of the bottom of the trench, whereby the punch-through between the bit line diffused layers can be effectively prevented, and resultantly writing can be efficiently performed. The impurity diffused region of a conduction type opposite to that of the bit line diffused layers is formed, surrounding the bit line diffused layers, whereby the extension of the depletion layer between the bit line diffused layers can be further suppressed, and resultantly the punch-through immunity can be further improved. The silicide film is formed by silicide process selectively on the bit line diffused layers, whereby the bit line diffused layer resistance can be drastically reduced.

[Modified Embodiments]

The present invention is not limited to the above-described embodiments and can cover other various modifications.

For example, the nonvolatile semiconductor memory device according to the first to the sixth embodiments is formed on a bulk silicon substrate 10 but may be formed on an SOI substrate. The use of an SOI substrate can drastically reduce parasitic capacitance, which contributes to the high speed operation.

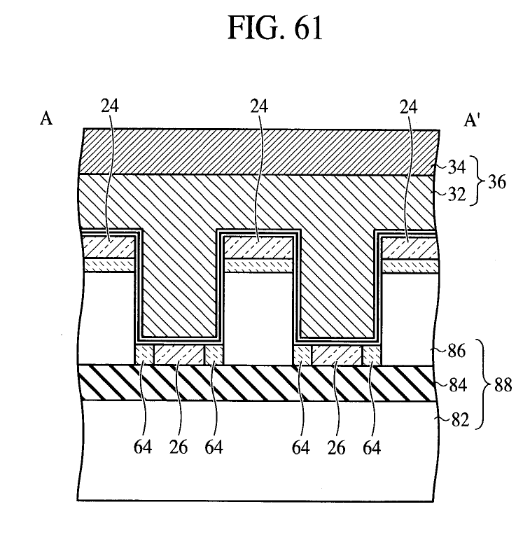

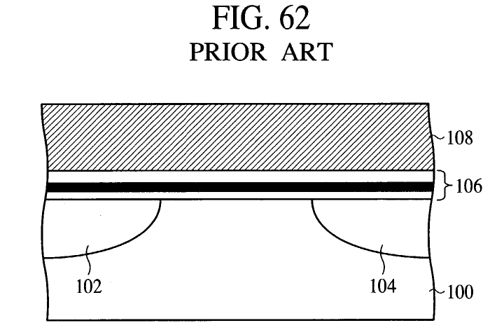

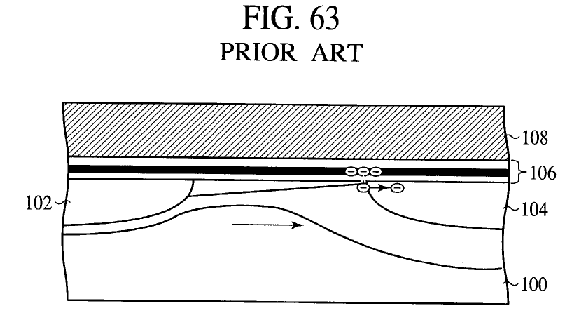

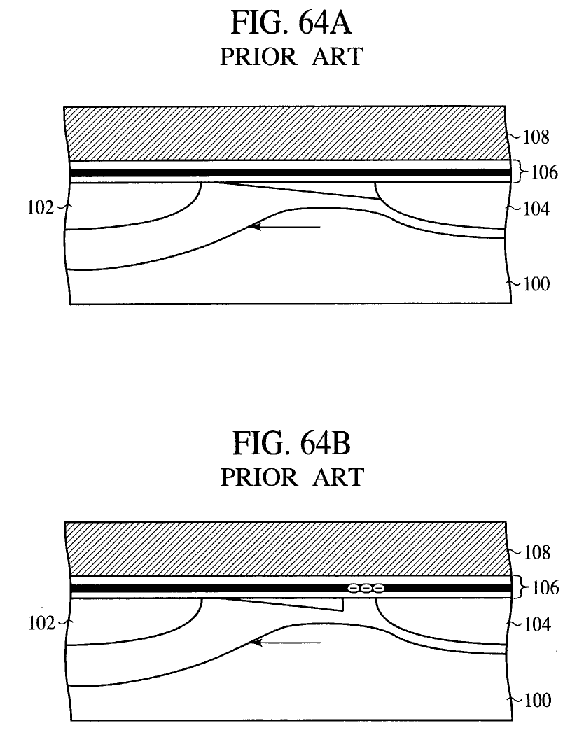

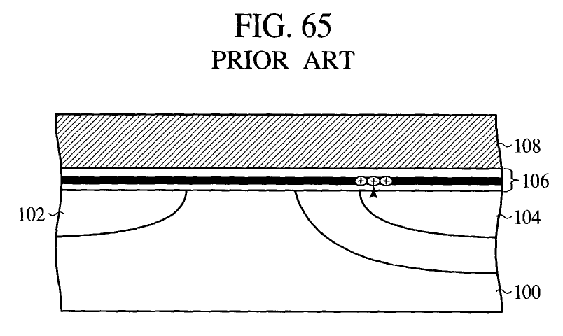

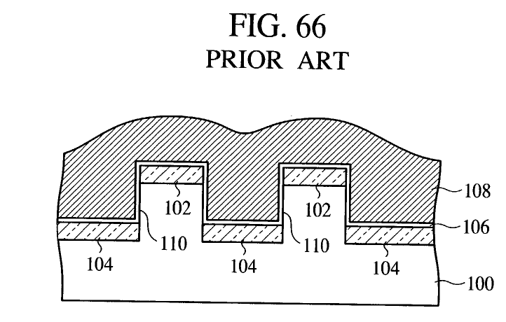

In the nonvolatile semiconductor memory device according to the second embodiment, as exemplified in FIG. 61, the nonvolatile semiconductor memory device is formed with the lower surface of the bit line diffused layer 26 in contact with the upper surface of the buried insulating layer 84 of the SOI substrate 88. Thus, the junction capacitance between the bit line diffused layer 26 and the substrate (SOI layer 86) can be drastically reduced. SOI substrates can be similarly used also in the nonvolatile semiconductor memory device according to the first and the third to the sixth embodiments.

In the above-described first, second, fifth and sixth embodiments, in forming the bit line diffused layer 26, offset from the corner of the bottom of the trench 16, the sidewall insulating film 20 is utilized, but as in the fourth embodiment, the sidewall conducting film 70 to be parts of the word lines 36 may be utilized.

In the above-described fifth embodiment, the method for forming the cobalt silicide film 72 selectively on the bit line diffused layers 24, 26, the word lines 36, the gate electrodes 38 and the source/drain diffused layers 48 is applied to the nonvolatile semiconductor memory device according to the second embodiment. In the above-described sixth embodiment, the method for forming the titanium silicide film 80 selectively on the bit line diffused layers 24, 26 and the source/drain diffused layers 48 is applied to the nonvolatile semiconductor memory device according to the second embodiment. However, these methods are applicable to the nonvolatile semiconductor memory device according to the first, the third and the fourth embodiments.

What is claimed is:

1. A nonvolatile semiconductor memory device comprising:
a semiconductor substrate of a first conduction type with a trench formed in a surface thereof;
a first impurity diffused region of a second conduction type formed in the surface other than a region where the trench is formed, of the semiconductor substrate;
a second impurity diffused region of the second conduction type formed in the semiconductor substrate at a bottom of the trench and having a width smaller than that of the trench;
a charge storage layer of an insulating layer formed on an inside surface of the trench; and
a conducting layer formed on the charge storage layer between the first impurity diffused region and the second impurity diffused region.

2. A nonvolatile semiconductor memory device according to claim 1, further comprising:
a third impurity diffused region of the first conduction type formed in the semiconductor substrate below the first impurity diffused region and in contact with the first impurity diffused region; and
a fourth impurity diffused region of the first conduction type formed in the semiconductor substrate at the bottom of the trench, surrounding the second impurity diffused region and having a width substantially equal to that of the trench.

3. A nonvolatile semiconductor memory device according to claim 1, wherein
the trench has a first width at a part nearer to the surface and has at a part nearer to the bottom a second width smaller than the first width, and has the inside surface stepped,
the second impurity diffused region has a width substantially equal to the second width.

4. A nonvolatile semiconductor memory device according to claim 1, further comprising:
a metal silicide film formed selectively on the first impurity diffused region and the second impurity diffused region.

5. A nonvolatile semiconductor memory device according to claim 4, wherein
the conducting layer includes a metal silicide film of the same material as the metal silicide film formed on the first impurity diffused region and the second impurity diffused region.

6. A nonvolatile semiconductor memory device according to claim 4, wherein
the conducting layer includes a metal silicide film of a material different from that of the metal silicide film formed on the first impurity diffused region and the second impurity diffused region.

7. A nonvolatile semiconductor memory device according to claim 1, wherein
the semiconductor substrate is an SOI substrate including a substrate, a buried insulating layer formed on the substrate and a semiconductor layer formed on the buried insulating layer, and
the second impurity diffused region has a bottom in contact with the buried insulating layer.

8. A nonvolatile semiconductor memory device comprising:
a semiconductor substrate of a first conduction type with a plurality of trenches formed in a surface thereof, the trenches extending in a first direction and being in parallel with each other;
a plurality of first impurity diffused regions of a second conduction type formed in the surface other than regions where the trenches are formed, of the semiconductor substrate, the first impurity diffused regions extending in the first direction;
a plurality of second impurity diffused regions of the second conduction type formed in the semiconductor substrate at bottoms of the trenches, the second impurity diffused regions extending in the first direction and having a width smaller than that of the trenches;
a charge storage layer of an insulating layer formed on inside surfaces of the trenches; and
a plurality of conducting layers formed on the charge storage layer, the conducting layers extending in a second direction intersecting the first direction and being in parallel with each other.

9. A nonvolatile semiconductor memory device according to claim 8, further comprising:
a plurality of third impurity diffused regions of the first conduction type formed in sidewalls of the trenches in regions between the conducting layers.

10. A nonvolatile semiconductor memory device according to claim 8, further comprising:
a plurality of fourth impurity diffused regions of the first conduction type formed in the semiconductor substrate below the first impurity diffused regions and in contact with the first impurity diffused regions; and
a plurality of fifth impurity diffused regions of the first conduction type formed in the semiconductor substrate at the bottoms of the trenches, surrounding the second impurity diffused regions and having a width substantially equal to that of the trench.

11. A nonvolatile semiconductor memory device according to claim 8, wherein
the trenches have the inside surfaces stepped, and have a first width at parts nearer to the surface and at parts nearer to the bottoms a second width smaller than the first width, and
the second impurity diffused regions have a width substantially equal to the second width.

12. A method for fabricating a nonvolatile semiconductor memory device comprising the steps of:
forming a trench in a surface of a semiconductor substrate of a first conduction type;
doping an impurity of a second conduction type in the semiconductor substrate with the trench formed in to form a first impurity diffused region of the second conduction type in the surface of the semiconductor substrate other than a region where the trench formed in and a second impurity diffused region of the second conduction type having a smaller width than the trench in the semiconductor substrate at a bottom of the trench, which are independent of each other;
forming a charge storage layer of an insulating layer on an inside surface of the trench; and
forming a conducting layer on the charge storage layer between the first impurity diffused region and the second impurity diffused region.

13. A method for fabricating a nonvolatile semiconductor memory device according to claim 12, wherein
in the step of forming a trench, a plurality of the trenches extending in the first direction and being in parallel with each other are formed; and
in the step of forming a conducting layer, a plurality of the conducting layers extending in a second direction intersecting the first direction and being in parallel with each other are formed.

14. A method for fabricating a nonvolatile semiconductor memory device according to claim 12, further comprising, after the step of forming the conducting layer, the step of:
doping an impurity of the first conduction type into the semiconductor substrate to form a third impurity diffused region of the first conduction type on the sidewalls of the trenches in regions between the conducting layers.

15. A method for fabricating a nonvolatile semiconductor memory device according to claim 10, further comprising the step of:
doping an impurity of the first conduction type in the semiconductor substrate to form a third impurity diffused region of the first conduction type in the semiconductor substrate below the first impurity diffused region and in contact with the first impurity diffused region, and a fourth impurity diffused region of the first conduction type having a width substantially equal to that of the trench in the semiconductor substrate at the bottom of the trench, surrounding the second impurity diffused region.

16. A method for fabricating a nonvolatile semiconductor memory device according to claim 10,
which further comprises, after the step of forming the trench, the step of forming a sidewall film, covering selectively a sidewall of the trench, and in which in the step of forming the first impurity diffused region and the second impurity diffused region, the impurity is doped with the sidewall film as a mask to form the second impurity diffused region having a width smaller than that of the trench.

17. A method for fabricating a nonvolatile semiconductor memory device according to claim 16,
which further comprises, between the step of forming the sidewall film and the step of forming the first impurity diffused region and a second impurity diffused region, the step of anisotropically etching the semiconductor substrate with the sidewall film as a mask to further deepen the trench to form the inside surface of the trench stepped to thereby form the trench having a first width at a part nearer to the surface and at a part nearer to the bottom a second width smaller than the first width, and
in which in the step of forming the first impurity diffused region and the second impurity diffused region, the second impurity diffused region having a width substantially equal to the second width is formed.

18. A method for fabricating a nonvolatile semiconductor memory device according to claim 17, wherein
the step of forming the sidewall film follows the step of forming the charge storage layer;
in the step of forming the sidewall film, the sidewall film of a conducting film is formed on the sidewall of the trench with the charge storage layer formed thereon; and
in the step of forming the conducting layer, the conducting layer containing the sidewall film as a part is formed.

19. A method for fabricating a nonvolatile semiconductor memory device according to claim 10, further comprising, after the step of forming the conducting layer, the step of:
forming a metal silicide film selectively on the first impurity diffused region and the second impurity diffused region.

20. A method for fabricating a nonvolatile semiconductor memory device according to claim 19, wherein
in the step of forming the metal silicide film, the metal silicide film is concurrently formed on the conducting layer.
